(19) United States
(12) Patent Application Publication
(10) Pub. No.: US 2025/0385223 A1
(43) Pub. Date: Dec. 18, 2025

(54) SEMICONDUCTOR DEVICE

(71) Applicant: Renesas Electronics Corporation, Tokyo (JP)

(72) Inventors: Yasutaka NAKASHIBA, Tokyo (JP); Toshiyuki HATA, Tokyo (JP)

(21) Appl. No.: 19/175,039

(22) Filed: Apr. 10, 2025

(30) Foreign Application Priority Data
Jun. 12, 2024 (JP) 2024-094918

(51) Int. Cl. H01L 25/07; H01L 23/00; H01L 23/495

(52) U.S. Cl. CPC H01L 25/072; H01L 23/49575; H01L 24/48; H01L 2224/48137; H01L 2224/48247

(57) ABSTRACT

A second semiconductor chip is mounted on a second die pad, and a first semiconductor chip and a third semiconductor chip are mounted on a first die pad spaced apart from the second die pad in a Y direction. The third semiconductor chip includes a transformer and is adjacent to the first semiconductor chip in an X direction. In plan view, a third side of the third semiconductor chip faces a first side of the first semiconductor chip, and a fourth side of the third semiconductor chip opposite the third side faces the second side of the second semiconductor chip. The first semiconductor chip and the third semiconductor chip are electrically connected with each other via a plurality of first wires. The second semiconductor chip and the third semiconductor chip are electrically connected with each other via a plurality of second wires.

### CROSS-REFERENCE TO RELATED APPLICATIONS

The disclosure of Japanese Patent Application No. 2024-094918 filed on Jun. 12, 2024 including the specification, drawings and abstract is incorporated herein by reference in its entirety.

### BACKGROUND

The present invention relates to a semiconductor device and for example, can suitably be applied to a semiconductor device having a plurality of semiconductor chips.

A semiconductor device in a form of a semiconductor package can be manufactured by mounting a semiconductor chip on a die pad, electrically connecting a pad electrode and a lead of the semiconductor chip via a wire, and sealing them with a resin.

There are disclosed techniques listed below.
[Patent Document 1] Japanese Unexamined Patent Application Publication No. 2023-181601

Patent Document 1 discloses a technique in which, in order to transmit signals from a semiconductor chip to another semiconductor chip, two coils provided in still another semiconductor chip are inductively coupled with each other to transmit electrical signals.

### SUMMARY

In the semiconductor device disclosed in the above-described Patent Document 1, achievement of size reduction is demanded. Alternatively, improvement in manufacturing yield is demanded.

Other problems and novel features of the present invention will become clear from the description of the present specification and the accompanying drawings.

According to one embodiment, a semiconductor device includes: a first chip mounting portion; a second chip mounting portion spaced apart from the first chip mounting portion; a first semiconductor chip mounted on the first chip mounting portion and including: a first side, a first circuit, and a plurality of first chip pads arranged along the first side and electrically connected with the first circuit; a second semiconductor chip mounted on the second chip mounting portion and including: a second side, a second circuit, and a plurality of second chip pads arranged along the second side and electrically connected with the second circuit; a third semiconductor chip mounted on the first chip mounting portion and including: a third side, a fourth side opposite the third side, two first conductor patterns magnetically or capacitively coupled with each other, a plurality of first pattern pads arranged along the third side and electrically connected with a one of the two first conductor patterns, and a plurality of second pattern pads arranged along the fourth side and electrically connected with an other of the two first conductor patterns; a plurality of first wires electrically connecting the plurality of first chip pads with the plurality of first pattern pads, respectively; a plurality of second wires electrically connecting the plurality of second chip pads with the plurality of second pattern pads, respectively; and a resin sealing body sealing the first semiconductor chip, the second semiconductor chip, the third semiconductor chip, the first chip mounting portion, the second chip mounting portion, the plurality of first wires, and the plurality of second wires, wherein the first chip mounting portion and the second chip mounting portion are adjacent to each other in a first direction, wherein a planar shape of the first semiconductor chip is formed of a quadrangle including the first side, wherein a planar shape of the second semiconductor is formed of a quadrangle including the second side, wherein a planar shape of the third semiconductor chip is formed of a quadrangle including the third side and the fourth side, wherein a length of the second side is greater than a length of each of the first side, the third side, and the fourth side, wherein the first semiconductor chip and the third semiconductor chip are adjacent to each other in a second direction orthogonal to the first direction, and wherein, in plan view, the first semiconductor chip and the third semiconductor chip are arranged along the second side of the second semiconductor chip such that the third side of the third semiconductor chip faces the first side of the first semiconductor chip and such that the fourth side of the third semiconductor chip faces the second side of the second semiconductor chip.

According to one embodiment, the size reduction of the semiconductor device can be achieved. In addition, the manufacturing yield of the semiconductor device can be enhanced. Alternatively, the size reduction of the semiconductor device can be achieved, and the manufacturing yield of the semiconductor device can also be achieved.

### BRIEF DESCRIPTION OF THE DRAWINGS

FIG. 1 is a circuit diagram illustrating an inverter circuit using a semiconductor device according to a first embodiment.

FIG. 2 is a top view of the semiconductor device according to the first embodiment.

FIG. 3 is a plan perspective view of the semiconductor device according to the first embodiment.

FIG. 4 is a plan perspective view of the semiconductor device according to the first embodiment.

FIG. 5 is a plan perspective view of the semiconductor device according to the first embodiment.

FIG. 6 is a bottom view of the semiconductor device according to the first embodiment.

FIG. 7 is a cross-sectional view of the semiconductor device according to the first embodiment.

FIG. 8 is a cross-sectional view of the semiconductor device according to the first embodiment.

FIG. 9 is a cross-sectional view of the semiconductor device according to the first embodiment.

FIG. 10 is a cross-sectional view schematically chips illustrating three semiconductor in the semiconductor device according to the first embodiment.

FIG. 11 is a cross-sectional view schematically illustrating the three semiconductor chips in the semiconductor device according to the first embodiment.

FIG. 12 is a plan perspective view of a semiconductor device according to a first study example.

FIG. 13 is a plan perspective view of a semiconductor device according to a second study example.

FIG. 14 is a plan perspective view of a semiconductor device according to a second embodiment.

FIG. 15 is a plan perspective view of the semiconductor device according to the second embodiment.

FIG. 16 is a circuit diagram illustrating an inverter circuit using a semiconductor device according to a third embodiment.

FIG. 17 is a plan perspective view of the semiconductor device according to the third embodiment.

FIG. 18 is a plan perspective view of the semiconductor device according to the third embodiment.

FIG. 19 is a plan perspective view of a semiconductor device according to a fourth embodiment.

FIG. 20 is a plan perspective view of the semiconductor device according to the fourth embodiment.

FIG. 21 is a circuit diagram illustrating a DC-DC converter circuit using a semiconductor device according to a fifth embodiment.

FIG. 22 is a plan perspective view of the semiconductor device according to the fifth embodiment.

FIG. 23 is a plan perspective view of the semiconductor device according to the fifth embodiment.

FIG. 24 is a plan perspective view of a semiconductor device according to a sixth embodiment.

FIG. 25 is a plan perspective view of the semiconductor device according to the sixth embodiment.

### DETAILED DESCRIPTION

In the embodiments described below, the invention will be described in a plurality of sections or embodiments if necessary for the sake of convenience. However, these sections or embodiments are not irrelevant to each other unless otherwise clearly specified, and one section or embodiment partially or entirely corresponds to another section or embodiment as a modification, detailed or supplementary description or the like. In addition, in the embodiments described below, when referring to the number of a component (including number of pieces, numerical value, amount and range), the number is not limited to a specified number and may be less than or greater than this number unless otherwise clearly specified or unless it is obvious from the context that the number is limited to the specified number in principle. Furthermore, in the embodiments described below, it goes without saying that each component (including an element step) is not indispensable unless otherwise clearly specified or unless it is obvious from the context that the component is indispensable in principle. Likewise, in the embodiments described below, when referring to a shape, a positional relation or the like of a component, a substantially approximate shape, a similar shape or the like is included unless otherwise clearly specified or unless it is obvious from the context that the shape, the positional relation or the like of the component differs in principle. The same applies to the above-described numerical value and range.

Hereinafter, embodiments of the present invention will be described in detail with reference to the drawings. Note that, in all of the drawings used to describe the embodiments, members having the same function are denoted by the same reference signs, and redundant descriptions thereof are omitted as appropriate. In addition, in the embodiments described below, descriptions of the same or similar portions are generally not repeated unless otherwise necessary.

Further, in the drawings used to describe the embodiments, hatched lines and the like are occasionally omitted even in cross-sectional view for the sake of clarity. Moreover, hatched lines may be added even in plan view for the sake of clarity.

### First Embodiment

### Regarding Circuit Configuration

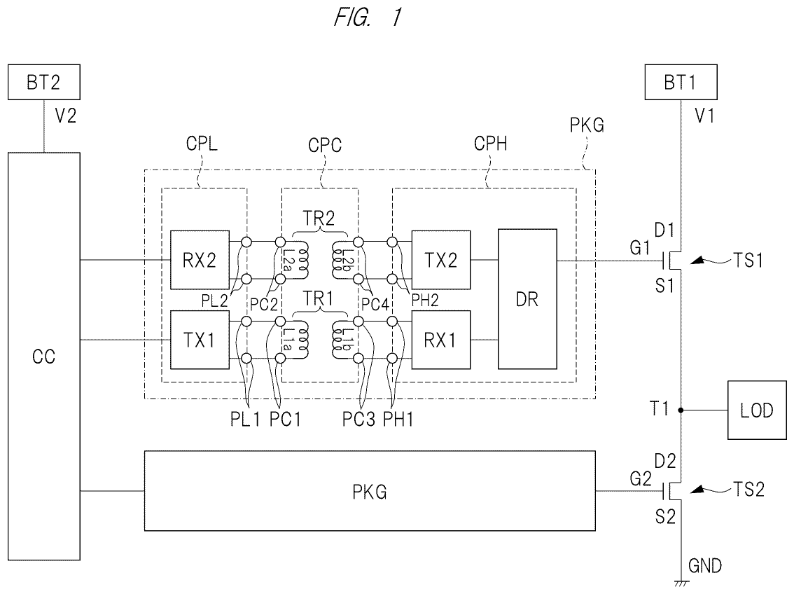

FIG. 1 is a circuit diagram illustrating an inverter circuit using a semiconductor device PKG according to the present embodiment. Note that, in FIG. 1, a portion surrounded by a dotted line denoted by a reference sign CPH is formed in a semiconductor chip CPH, a portion surrounded by a dotted line denoted by a reference sign CPL is formed in a semiconductor chip CPL, a portion surrounded by a dotted line denoted by a reference sign CPC is formed in a semiconductor chip CPC, and a portion surrounded by a one-dot chain line denoted by a reference sign PKG is formed in the semiconductor device PKG. The inverter circuit illustrated in FIG. 1 adopts two semiconductor devices PKG. In FIG. 1, for simplification of the drawings, a circuit configuration of the semiconductor device PKG connected to a power transistor TS2 is omitted, and the circuit configuration of the semiconductor device PKG connected to the power transistor TS2 is basically the same as that of the semiconductor device PKG connected to a power transistor TS1.

The semiconductor device PKG used for the inverter circuit illustrated in FIG. 1 includes three semiconductor chips CPC, CPL, and CPH. The semiconductor chip CPL has a transmitting circuit TX1 and a receiving circuit RX2 formed therein. The semiconductor chip CPH has a receiving circuit RX1, a transmitting circuit TX2, and a drive circuit (control circuit) DR formed therein. CPC has a transformer TR1 The semiconductor chip including a plurality of (two, in this case) coils Lla and L1b magnetically coupled with each other and a transformer TR2 including a plurality of (two, in this case) coils L2a and L2b magnetically coupled with each other formed therein. In addition, the inverter circuit illustrated in FIG. 1 also has a control circuit CC, and this control circuit CC is formed in another semiconductor chip provided outside the semiconductor package PKG.

The transmitting circuit TX1 and the receiving circuit RX1 are circuits for transmitting signals from the control circuit CC to a drive circuit DR. The transmitting circuit TX1 converts the signal transmitted from the control circuit CC to the transmitting circuit TX1 and transmits the converted signal to the receiving circuit RX1 via the transformer TR1. The receiving circuit RX1 converts the signal received from the transmitting circuit TX1 via the transformer TR1 and transmits the received signal to the drive circuit DR.

The transmitting circuit TX2 and the receiving circuit RX2 are circuits for transmitting signals from the drive circuit DR to the control circuit CC. The transmitting circuit TX2 converts the signal transmitted from the drive circuit DR to the transmitting circuit TX2 and transmits the converted signal to the receiving circuit RX2 via the transformer TR2. The receiving circuit RX2 converts the signal received from the transmitting circuit TX2 via the transformer TR2 and transmits the converted signal to the control circuit CC.

The inverter circuit illustrated in FIG. 1 has power transistors TS1 and TS2. The power transistor TS1 is a transistor for a high-side switch (a switch for high potential side), and the power transistor TS2 is a transistor for a low-side switch (a switch for low potential side). The power transistor TS1 and the power transistor TS2 are individually formed in separate semiconductor chips provided outside the semiconductor package PKG.

In the following description, a case in which the power transistors TS1 and TS2 are power metal oxide semiconductor field effect transistors (MOSFETS) will be described. As the power transistors TS1 and TS2, an insulated gate bipolar transistor (IGBT) can also be applied thereto, and in this case, in the following description regarding the power transistors TS1 and TS2, a “source” may be rephrased as an “emitter,” and a “drain” may be rephrased as a “collector.”

In addition, in the present application, when MOSFET is referred to, it includes not only a metal insulator semiconductor field effect transistor (MISFET) in which an oxide film (oxide silicon film) is used for a gate insulating film but also a MISFET in which an insulating film other than oxide film is used for a gate insulating film.

The power transistor TS1 and the power transistor TS2 are connected in series, and a source (S1) of the power transistor TS1 is connected to a drain (D2) of the power transistor TS2. A drain (D1) of the power transistor TS1 is supplied with power supply potential (power supply voltage) V1 from a power supply (battery) BT1. In addition, the control circuit CC is supplied with power supply potential (power supply voltage) V2 from a power supply (battery) BT2. The power supply potential V1 supplied to the drain (D1) of the power transistor TS1 is much higher than the power supply potential V2 supplied to the control circuit CC (for example, several to several tens of volts higher), and is, for example, equal to or higher than 100 V (several hundreds of volts). The source (S2) of the power transistor TS2 is supplied with a reference potential lower than the power supply potential V1 and, for example, is supplied with ground potential (GND). A gate (G1) of the power transistor TS1 and a gate (G2) of the power transistor TS2 are each connected to a corresponding drive circuit DR.

Note that, in the present embodiment, the same number of semiconductor devices PKG as the number of the power transistors TS1 and TS2 are used. In this case, the drive circuit DR included in the semiconductor device PKG provided for the power transistor TS1 controls voltage of a gate (G1) of the power transistor TS1, and the drive circuit DR included in the semiconductor device PKG provided for the power transistor TS2 controls voltage of a gate (G2) power of the transistor TS2. As an alternative, such a case in which one semiconductor device PKG is used for two power transistors TS1 and TS2 is considerable, but in that case, the drive circuit DR included in the semiconductor device PKG shared by the two power transistors TS and TS2 controls voltages of the gates (G1 and G2).

According to the signal (control signal) supplied from the control circuit CC to the drive circuit via the transmitting circuit TX1, the transformer TR1, and the receiving circuit RX1, gate voltage to be supplied from the drive circuit DR to each of the gates (G1 and G2) of the power transistors TS1 and TS2 is controlled, so that operations of the power transistors TR1 and TR2 can be controlled.

A terminal T1 provided between the source (S1) of the power transistor TS1 and the drain (D2) of the power transistor TS2 is an output terminal of the inverter circuit. The terminal T1 is connected to a load LOD. The load LOD is, for example, a coil of a motor. A direct current (DC) power supplied to the inverter circuit is converted into an alternating current (AC) power in the inverter circuit and supplied to the load LOD.

The transformer TR1 is interposed between the transmitting circuit TX and the receiving circuit RX1, and the transformer TR2 is interposed between the transmitting circuit TX2 and the receiving circuit RX2. The control circuit CC can transmit a signal (control signal) to the drive circuit DR via the transmitting circuit TX1, the transformer TR1, and the receiving circuit RX1. In addition, the drive circuit DR can transmit a signal to the control circuit CC via the transmitting circuit TX2, the transformer TR2, and the receiving circuit RX2. The coils L1a, L1b, L2a, and L2b can also be regarded as inductors.

The transformer TR1 is formed by the coils L1a and L1b formed in the semiconductor chip CPC, and the coil L1a and the coil Lib are not connected by a conductor and are magnetically coupled with each other. Hence, when current flows in the coil L1a, according to change in the current, an induced electromotive force is generated in the coil L1b, and inductive current flows therein. The coil L1a is a primary coil, and the coil Lib is a secondary coil. With use of these coils, a signal is transmitted from the transmitting circuit TX1 to the coil L1a(primary coil) of the transformer TR1, and current flows. This current causes inductive current (or an induced electromotive force) to be generated in the coil L1b (secondary coil) of the transformer TR1, and the generated inductive current is sensed (received) by the receiving circuit RX1, so that the signal corresponding to the signal transmitted by the transmitting circuit TX1 can be received by the receiving circuit RX1.

The transformer TR2 is formed by the coils L2a and L2b formed in the semiconductor chip CPC, and the coil L2a and the coil L2b are not connected by a conductor and are magnetically coupled with each other. Hence, when current flows in the coil L2b, according to change in the current, an induced electromotive force is generated in the coil L2a, and inductive current flows therein. The coil L2b is a primary coil, and the coil L2a is a secondary coil. With use of these coils, a signal is transmitted from the transmitting circuit TX2 to the coil L2b (primary coil) of the transformer TR2, and current flows. This current causes inductive current (or an induced electromotive force) to be generated in the coil L2a (secondary coil) of the transformer TR2, and the generated inductive current is sensed (received) by the receiving circuit RX2, so that the signal corresponding to the signal transmitted by the transmitting circuit TX2 can be received by the receiving circuit RX2.

Through a passage from the transmitting circuit TX1 through the transformer TR1 to the receiving circuit RX1 and a passage from the transmitting circuit TX2 through the transformer TR2 to the receiving circuit RX2, it is possible to transmit signals between the semiconductor chip CPL and the semiconductor chip CPH.

The semiconductor chip CPL and the semiconductor chip CPH are different from each other in voltage level. For example, the semiconductor chip CPL is electrically connected to a low voltage region in which a circuit (for example, the control circuit CC) operating or driving at a low voltage (for example, several to several tens of volts) is included, via a wire BW, a lead LD (specifically, a lead LD2), and the like to be described later. In addition, the semiconductor chip CPH is electrically connected to a high voltage region in which a circuit (for example, the power transistors TS1 and TS2) operating or driving at a voltage higher than the low voltage (for example, equal to or higher than 100 V) is included, via a wire BW, a lead LD (specifically, a lead LD1), and the like to be described later. However, signal transmission between the semiconductor chips CPL and CPH are made via the transformers TR1 and TR2, so that signal transmission between circuits having different voltages is possible.

Note that, in FIG. 1, a case in which the control circuit CC is incorporated in a semiconductor chip other than the semiconductor chips CPC, CPH, and CPL is illustrated. As another alternative, a part or all of the control circuit CC can be incorporated in the semiconductor chip CPL as well.

### Regarding Structure of Semiconductor Device

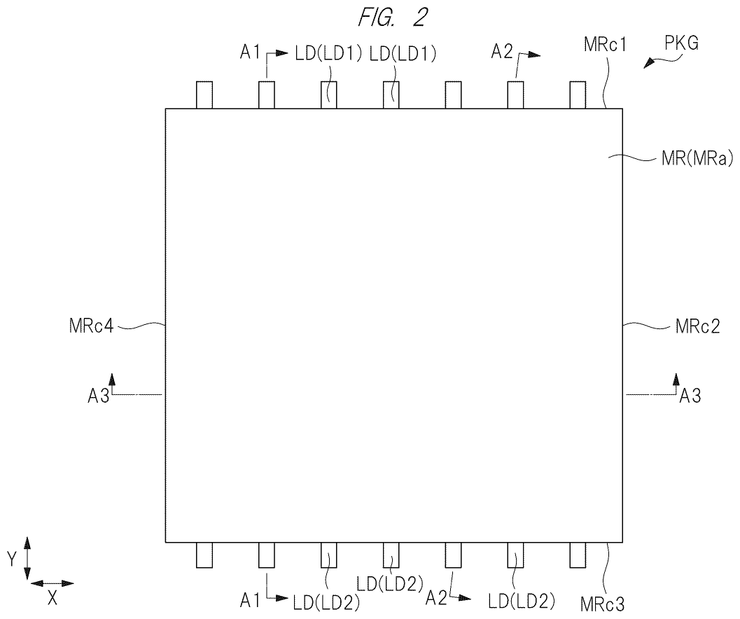

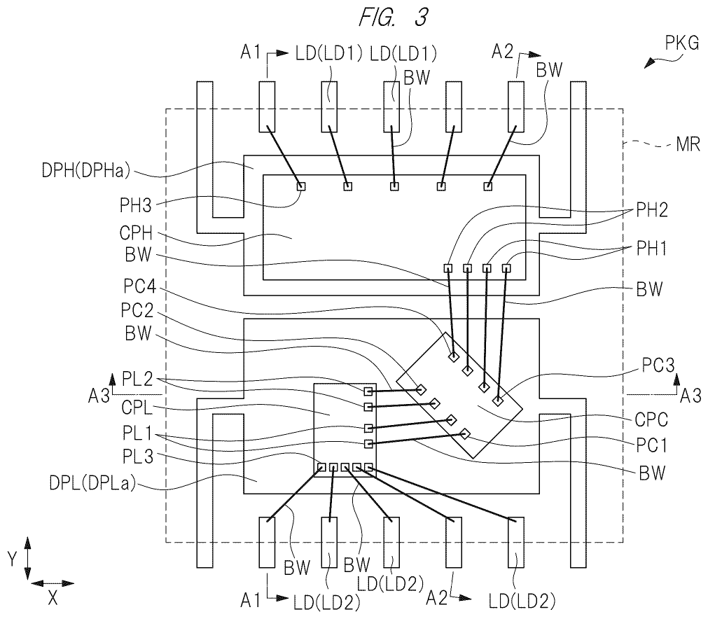

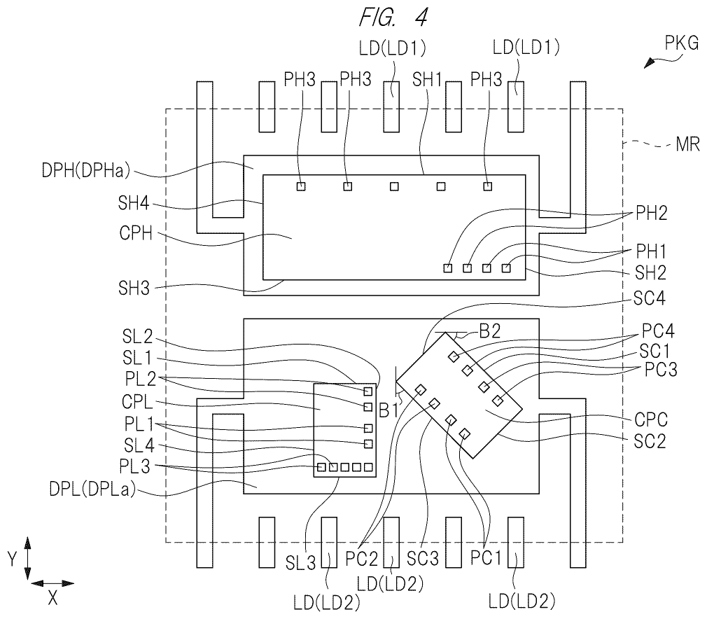

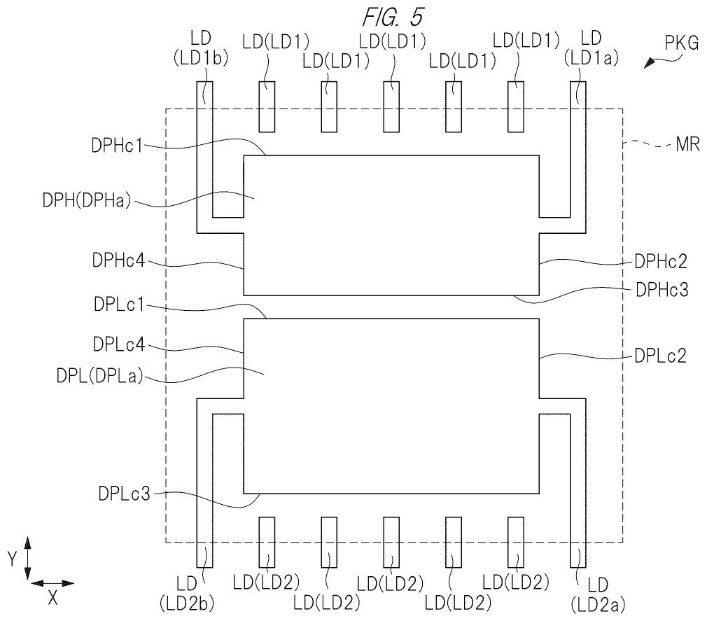

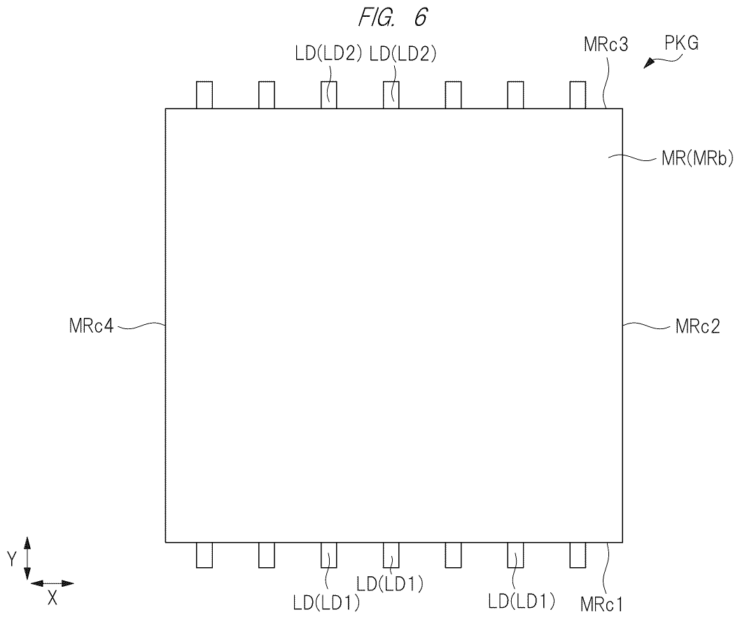

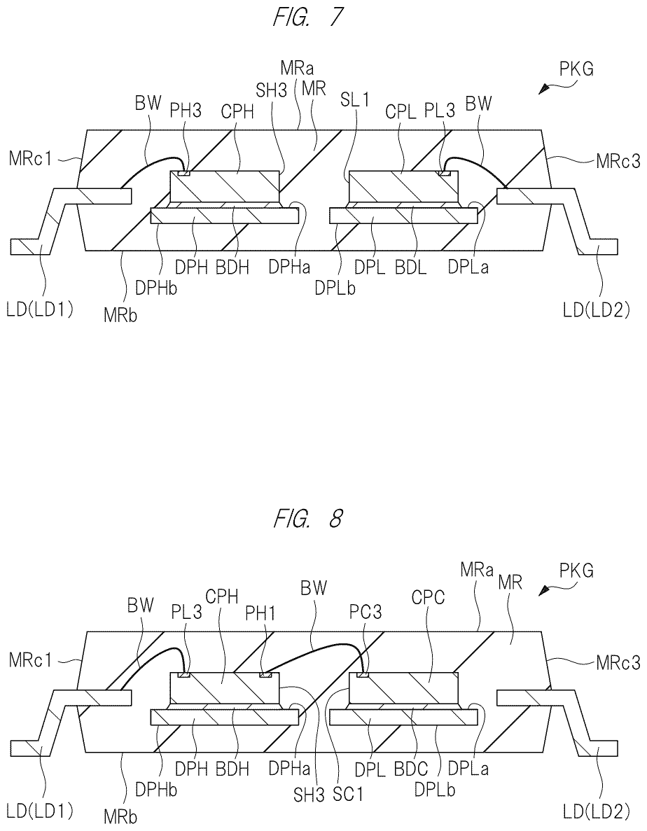

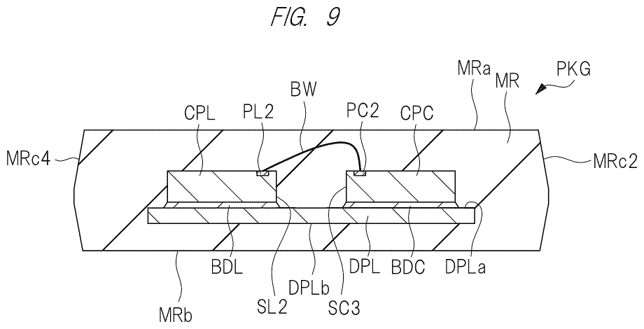

FIG. 2 is a top view of the semiconductor device PKG according to the present embodiment. FIG. 3, FIG. 4, and FIG. 5 are plan perspective views of the semiconductor device PKG. FIG. 6 is a bottom view (back surface view) of the semiconductor device PKG. FIG. 7, FIG. 8, and FIG. 9 are cross-sectional views of the semiconductor device PKG. FIG. 3 illustrates a plan perspective view of an upper surface side of the semiconductor device PKG when seen through a sealing portion MR. In addition, FIG. 4 illustrates a plan perspective view of the upper surface side of the semiconductor device PKG when further seen through (omitting) the wires BW in FIG. 3. In addition, FIG. 5 illustrates a plan perspective view of the upper surface side of the semiconductor device PKG when still seen further through (omitting) the semiconductor chips CPC, CPH, and CPL in FIG. 4. In FIG. 3, FIG. 4, and FIG. 5, the position of an outer periphery of the sealing portion MR is indicated by a dotted line. In addition, a cross-sectional view of the semiconductor device PKG taken along a line A1-A1 in FIG. 2 and FIG. 3 substantially corresponds to FIG. 7. A cross-sectional view of the semiconductor device PKG taken along a line A2-A2 in FIG. 2 and FIG. 3 substantially corresponds to FIG. 8. A cross-sectional view of the semiconductor device PKG taken along a line A3-A3 in FIG. 2 and FIG. 3 substantially corresponds to FIG. 9. In addition, in FIG. 2 through FIG. 6, an X direction and a Y direction are indicated. Here, the X direction and the Y direction are orthogonal to each other, and more specifically, intersect with each other at a right angle.

The semiconductor device (semiconductor package) PKG according to the present embodiment illustrated in FIG. 2 through FIG. 9 is a semiconductor device in a form of a resin-sealed semiconductor package, and in this case is a semiconductor device in a form of a small outline package (SOP). In the following description, with reference to FIG. 2 through FIG. 9, the configuration of the semiconductor device PKG will be described.

The semiconductor device PKG according to the present embodiment illustrated in FIG. 2 through FIG. 9 includes three semiconductor chips CPC, CPH, and CPL, a die pad DPL on which the two semiconductor chips CPC and CPL are mounted, a die pad DPH on which the one semiconductor chip CPH is mounted, a plurality of wires (bonding wires) BW, a plurality of leads LD, and a sealing portion MR sealing these elements.

The sealing portion MR as a resin sealing body includes, for example, a resin material such as a thermosetting resin material, and can also include a filler or the like. For example, the sealing portion MR can be formed by use of an epoxy resin including a filler.

The sealing portion MR has an upper surface MRa serving as one main surface, a lower surface (a back serving as the other surface or a bottom surface) MRb main surface opposite to the upper surface MRa, and side surfaces MRc1, MRc2, MRc3, and MRc4 which intersect with the upper surface MRa and the lower surface MRb.

The side surfaces MRc1 and MRc3 are substantially parallel to the X direction, and the side surfaces MRc2 and MRc4 are substantially parallel to the Y direction. In the sealing portion MR, the side surface MRc1 and the side surface MRc3 face each other, the side surfaces MRc2 and the side surface MRc4 face each other, the side surface MRc1 intersects with the side surfaces MRc2 and MRc4, and the side surface MRc3 intersects with the side surfaces MRc2 and MRc4. In addition, each of the upper surface MRa and the lower surface MRb is a plane parallel to both the X direction and the Y direction. A planar shape of the sealing portion MR, i.e., a planar shape of the upper surface MRa and the lower surface MRb of the sealing portion MR is, for example, rectangular.

Each of the plurality of leads LD included in the semiconductor device PKG has a portion sealed in the sealing portion MR and a remaining portion protruding from the side surface of the sealing portion MR outside the sealing portion MR. In the following description, a portion of the lead LD positioned in the sealing portion MR is called an inner lead portion, and a portion of the lead LD positioned outside the sealing portion MR is called an outer lead portion. A plated layer (not illustrated) such as a solder plated layer can also be formed on the outer lead portion of the lead LD.

Note that the semiconductor device PKG according to the present embodiment has a structure in which a part of each of the leads LD (outer lead portion) protrudes from the side surface of the sealing portion MR, and the following description will be given on the basis of this structure. However, the semiconductor device PKG is not limited to this structure. For example, a configuration in which each of the leads LD scarcely protrudes from the side surface of the sealing portion MR and a part of each of the leads LD is exposed on the lower surface MRb of the sealing portion MR (small outline nonleaded package (SON) type configuration) or the like can also be adopted.

The plurality of leads LD included in the semiconductor device PKG include a plurality of leads LD positioned on the side surface MRc1 side of the sealing portion MR, and a plurality of leads LD positioned on the side surface MRc3 of the sealing portion MR. In the case of FIG. 2 through FIG. 9, a lead LD is not disposed on the sides of the side surfaces MRc2 and MRc4 of the sealing portion MR. In the following description, the leads LD positioned on the side surface MRc1 side of the sealing portion MR are called leads LD1. In addition, the leads LD positioned on the side surface MRc3 side of the sealing portion MR are called leads LD2. The outer lead portion of each of the leads LD1 protrudes from the side surface MRc1 of the sealing portion MR outside the sealing portion MR. In addition, the outer lead portion of each of the leads LD2 protrudes from the side surface MRc3 of the sealing portion MR outside the sealing portion MR. The outer lead portion of each of the leads LD is bent such that a lower surface close to an end portion of the outer lead portion is positioned substantially flush with the lower surface MRb of the sealing portion MR. The outer lead portion of each of the leads LD functions as a terminal portion for external connection (external terminal) of the semiconductor device PKG.

The die pad DPL is a chip mounting portion on which the two semiconductor chips CPC and CPL are mounted, and the die pad DPH is a chip mounting portion on which the semiconductor chip CPH is mounted. The die pad DPH and the die pad DPL are spaced from each other in the Y direction, and a part of the sealing portion MR is interposed between the die pad DPH and the die pad DPL.

Among the die pads DPH and DPL, the die pad DPH is positioned closer to the side surface MRc1 of the sealing portion MR, and the die pad DPL is positioned closer to the side surface MRc3 of the sealing portion MR. Specifically, in the Y direction, the die pad DPH is positioned between the die pad DPL and the side surface MRc1 of the sealing portion MR, and the die pad DPL is positioned between the die pad DPH and the side surface MRc3 of the sealing portion MR. Each of the die pads DPH and DPL is sealed in the sealing portion MR and is not exposed from the sealing portion MR.

The die pads DPH and DPL and the plurality of leads LD are formed of conductors, and preferably are formed of a metal material such as copper (Cu) or a copper alloy. In addition, the die pads DPH and DPL and the plurality of leads LD are preferably formed of the same material. As such, manufacturing the semiconductor device PKG using the lead frame becomes easier.

The die pad DPH has an upper surface DPHa which is a main surface on a side on which the semiconductor chip CPH is mounted, a lower surface (back surface) DPHb which is the other main surface opposite thereto, and side surfaces DPHc1, DPHc2, DPHc3, and DPHc4 which are orthogonal to the upper surface DPHa and the lower surface DPHb. In the die pad DPH, the side surface DPHc1 is a side surface positioned on the side surface MRc1 side of the sealing portion MR. The side surface DPHc2 is a side surface positioned on the side surface MRc2 of the sealing portion MR. The side surface DPHc3 is a side surface positioned on the side surface MRc3 side of the sealing portion MR. The side surface DPHc4 is a side surface positioned on the side surface MRc4 side of the sealing portion MR. In the die pad DPH, the side surface DPHc1 and the side surface DPHc3 are positioned opposite to each other, and the side surface DPHc2 and the side surface DPHc4 are positioned opposite to each other. The side surface DPHc1 is orthogonal to the side surfaces DPHc2 and DPHc4, and the side surface DPHc3 is orthogonal to the side surfaces DPHc2 and DPHc4.

In addition, the die pad DPL has an upper surface DPLa which is a main surface on a side on which the semiconductor chips CPC and CPL are mounted, a lower surface (back surface) DPLb which is the other main surface opposite thereto, side surfaces DPLc1, DPLc2, DPLc3, and DPLc4 which are orthogonal to the upper surface DPLa and the lower surface DPLb. In the die pad DPL, the side surface DPLc1 is a side surface positioned on the side surface MRc1 side of the sealing portion MR, the side surface DPLc2 is a side surface positioned on the side surface MRc2 side of the sealing portion MR, the side surface DPLc3 is a side surface positioned on the side surface MRc3 of the sealing portion MR, and the side surface DPLc4 is a side surface positioned on the side surface MRc4 side of the sealing portion MR. In the die pad DPL, the side surface DPLc1 and the side surface DPLc3 are positioned opposite to each other, and the side surface DPLc2 and the side surface DPLc4 are positioned opposite to each other. The side surface DPLc1 is orthogonal to the side surfaces DPLc2 and DPLc4, and the side surface DPLc3 is orthogonal to the side surfaces DPLc2 and DPLc4. The side surface DPHc3 of the die pad DPH and the side surface DPLc1 of the die pad DPL face each other with a part of the sealing portion MR interposed therebetween.

The side surfaces DPHc1 and DPHc3 of the die pad DPH are substantially parallel to the side surfaces DPLc1 and DPLc3 of the die pad DPL in the X direction. The side surfaces DPHc2 and DPHc4 of the die pad DPH are substantially parallel to the side surfaces DPLc2 and DPLc4 of the die pad DPL in the Y direction. The upper surface DPHa and the lower surface DPHb of the die pad DPH and the upper surface DPLa and the lower surface DPLb of the die pad DPL are each a plane substantially parallel to both the X direction and the Y direction. A planar shape of each of the die pads DPH and DPL is, for example, rectangular.

Among the plurality of leads LD positioned on the side surface MRc1 side of the sealing portion MR, an inner lead portion of a lead LD1a is integrally coupled with the side surface DPHc2 of the die pad DPH, and an inner lead portion of a lead LD1b is integrally coupled with the side surface DPHc4 of the die pad DPH. The leads LD1a and LD1b function as a suspension lead which supports the die pad DPH to a frame of the lead frame at a time of manufacturing the semiconductor device PKG. In addition, among the plurality of leads LD positioned on the side surface MRc3 side of the sealing portion MR, an inner lead portion of a lead LD2a is integrally coupled with the side surface DPLc2 of the die pad DPL, and an inner lead portion of a lead LD2b is integrally coupled with the side surface DPLc4 of the die pad DPL. The leads LD2a and LD2b function as a suspension lead which supports the die pad DPL to a frame of the lead frame at a time of manufacturing the semiconductor device PKG. On the side surface MRc1 side of the sealing portion MR, the plurality of leads LD (LD1) are arranged in the X direction, and in this layout, the lead LD1a and the lead LD1b are positioned at opposite ends. In addition, on the side surface MRc3 side of the sealing portion MR, the plurality of leads LD (LD2) are arranged in the X direction, and in this layout, the leads LD2a and the lead LD2b are positioned at opposite ends.

Each of the three semiconductor chips CPC, CPH, and CPL has a front surface which is one main surface, and a back surface which is the other main surface opposite to the front surface. A planar shape of each of the semiconductor chips CPC, CPH, and CPL is quadrangular, and preferably is rectangular. Hence, in plan view, the semiconductor chip CPC has four sides SC1, SC2, SC3, and SC4, the semiconductor chip CPH has four sides SH1, SH2, SH3, and SH4, and the semiconductor chip CPL has four sides SL1, SL2, SL3, and SL4. Note that each side of the semiconductor chips CPC, CPH, and CPL is a side forming an outer periphery of the planar shape of the semiconductor chip and is formed of each side surface of the semiconductor chip. A plane size (plane area) of the semiconductor chip CPH is larger than a plane size (plane area) of each of the semiconductor chip CPL and the semiconductor chip CPC. In addition, a length of the side SH3 of the semiconductor chip CPH is greater than each length of the sides SL1, SL2, SL3, and SL4 of the semiconductor chip CPL. In addition, the length of the side SH3 of the semiconductor chip CPH is greater than each length of the sides SC1, SC2, SC3, and SC4 of the semiconductor chip CPC.

The semiconductor chip CPH is mounted on the upper surface DPHa of the die pad DPH via a bonding material BDH, with the back surface of the semiconductor chip CPH facing the die pad DPH. In addition, the semiconductor chip CPC is mounted on the upper surface DPLa of the die pad DPL via a bonding material BDC, with the back surface of the semiconductor chip CPC facing the die pad DPL. In addition, the semiconductor chip CPL is mounted on the upper surface DPLa of the die pad DPL via a bonding material BDL, with the back surface of the semiconductor chip CPL facing the die pad DPL. Specifically, among the semiconductor chips CPC, CPH, and CPL, the semiconductor mounted on the die pad DPH, and the chip CPH is semiconductor chips CPC and CPL are mounted on the die pad DPL.

On the upper surface DPLa of the die pad DPL, a region in which the semiconductor chip CPC is mounted and a region in which the semiconductor chip CPL is mounted are spaced apart from each other (more specifically, spaced apart from each other in the X direction). In other words, the semiconductor chip CPC and the semiconductor chip CPL are not stacked on top of another and are arranged in the X direction to be spaced apart from each other on the upper surface DPLa of the die pad DPL. More specifically, the semiconductor chip CPC and the semiconductor chip CPL arranged on the upper surface DPLa of the die pad DPL are adjacent to each other in the X direction.

In plan view, the die pad DPL and the die pad DPH are adjacent to each other in the Y direction. Hence, in plan view, the semiconductor chip CPL and the semiconductor chip CPH are adjacent to each other in the Y direction. In addition, in plan view, the semiconductor chip CPC and the semiconductor chip CPH are adjacent to each other in the Y direction. In plan view, the semiconductor chip CPC and the semiconductor chip CPL are disposed inside the upper surface DPLa of the die pad DPL. In addition, in plan view, the semiconductor chip CPH is disposed inside the upper surface DPHa of the die pad DPH. Note that a plan view corresponds to a case of being viewed from a plane parallel to both the X direction and the Y direction.

The bonding materials BDC, BDH, and BDL can adopt a conductive bonding material such as a silver paste. The back surface of the semiconductor chip CPH is bonded and fixed to the die pad DPH via the bonding material BDH, the back surface of the semiconductor chip CPC is bonded and fixed to the die pad DPL via the bonding material BDC, and the back surface of the semiconductor chip CPL is bonded and fixed to the die pad DPL via the bonding material BDL. The semiconductor chips CPC, CPH, and CPL are sealed in the sealing portion MR and are not exposed from the sealing portion MR.

As the bonding materials BDC, BDH, and BDL, a bonding material having an insulating property can be used as well. However, in a case in which a conductive bonding material is used as the bonding materials BDC, BDH, and BDL, an advantage in which heat generated in the semiconductor chips CPC, CPH, and CPL is caused to easily conduct to the die pads DPH and DPL via the bonding materials BDC, BDH, and BDL is obtained.

Among the four sides SH1, SH2, SH3, and SH4 of the semiconductor chip CPH, the side SH1 and the side SH3 are positioned opposite to each other, and the side SH2 and the side SH4 are positioned opposite to each other. The side SH1 is orthogonal to the sides SH2 and SH4, and the side SH3 is orthogonal to the sides SH2 and SH4. The sides SH1 and SH3 of the semiconductor chip CPH is substantially parallel to the X direction, and the sides SH2 and SH4 of the semiconductor chip CPH are substantially parallel to the Y direction. Each of the front surface and the back surface of the semiconductor chip CPH is substantially parallel to both the X direction and the Y direction.

Among the sides SH1 and SH3 of the semiconductor chip CPH, the side SH1 of the semiconductor chip CPH is positioned closer to the side surface DPHc1 of the die pad DPH, and the side SH3 of the semiconductor chip CPH is positioned closer to the side surface DPHc3 of the die pad DPH. Specifically, in the Y direction, the side SH1 of the semiconductor chip CPH is positioned between the side surface DPHc1 of the die pad DPH and the side SH3 of the semiconductor chip CPH, and the side SH3 of the semiconductor chip CPH is positioned between the side surface DPHc3 of the die pad DPH and the side SH1 of the semiconductor chip CPH.

Among the four sides SL1, SL2, SL3, and SL4 of the semiconductor chip CPL, the side SL1 and the side SL3 are positioned opposite to each other, and the side SL2 and the side SL4 are positioned opposite to each other. The side SL1 is orthogonal to the sides SL2 and SL4, and the side SL3 is orthogonal to the sides SL2 and SL4. The sides SL1 and SL3 of the semiconductor chip CPL are substantially parallel to the X direction, and the sides SL2 and SL4 of the semiconductor chip CPL are substantially parallel to the Y direction. Each of the front surface and the back surface of the semiconductor chip CPL is parallel to both the X direction and the Y direction.

Among the sides SL1 and SL3 of the semiconductor chip CPL, the side SL1 of the semiconductor chip CPL is positioned closer to the side surface DPLc1 of the die pad DPL, and the side SL3 of the semiconductor chip CPL is positioned closer to the side surface DPLc3 of the die pad DPL. Specifically, in the Y direction, the side SL1 of the semiconductor chip CPL is positioned between the side surface DPLc1 of the die pad DPL and the side SL3 of the semiconductor chip CPL, and the side SL3 of the semiconductor chip CPL is positioned between the side surface DPLc3 of the die pad DPL and the side SL1 of the semiconductor chip CPL.

Among the four sides SC1, SC2, SC3, and SC4 of the semiconductor chip CPC, the side SC1 and the side SC3 are positioned opposite to each other, and the side SC2 and the side SC4 are positioned opposite to each other. The side SC1 is orthogonal to the sides SC2 and SC4, and the side SC3 is orthogonal to the sides SC2 and SC4. Each of the front surface and the back surface of the semiconductor chip CPC is substantially parallel to both the X direction and the Y direction.

Each of the sides SC1, SC2, SC3, and SC4 of the semiconductor chip CPC is inclined to the X direction and inclined to the Y direction. In other words, in plan view, the semiconductor chip CPC is disposed to be inclined. Hence, each of the sides SC1, SC2, SC3, and SC4 of the semiconductor chip CPC is not parallel to either the X direction or the Y direction. An inclined angle of each side SC1, SC2, SC3, or SC4 of the semiconductor chip CPC relative to the X direction is preferably in a range of 40 degrees to 50 degrees, and is most preferably 45 degrees.

Among a corner portion formed by the sides SC1 and SC2, a corner portion formed by the sides SC2 and SC3, a corner portion formed by the sides SC3 and SC4, and a corner portion formed by the sides SC4 and SC1 of the semiconductor chip CPC, the corner portion formed by the sides SC4 and SC1 is closest to the side surface DPLc1 of the die pad DPL, and the corner portion formed by the sides SC2 and SC3 is closest to the side surface DPLc3 of the die pad DPL.

In plan view, among the four corner portions of the semiconductor chip CPC, a distance (distance in the Y direction) between the corner portion formed by the sides Sc4 and SC1 and the semiconductor chip CPH is smaller than a distance (distance in the Y direction) between the other corner portions of the semiconductor chip CPC and the semiconductor chip CPH. In addition, in plan view, among the four corner portions of the semiconductor chip CPC, a distance (distance in the X direction) between the corner portion formed by the sides SC3 and SC4 and the semiconductor chip CPL is smaller than a distance (distance in the X direction) between the other corner portions of the semiconductor chip CPC and the semiconductor chip CPL.

In plan view, the side SC3 of the semiconductor chip CPC and the side SL2 of the semiconductor chip CPL face each other, and the side SC1 of the semiconductor chip CPC and the side SH3 of the semiconductor chip CPH face each other. Note that, in plan view, the side SC3 of the semiconductor chip CPC is inclined to the side SL2 of the semiconductor chip CPL, and the side SC1 of the semiconductor chip CPC is inclined to the side SH3 of the semiconductor chip CPH. In addition, in plan view, the side SL1 of the semiconductor chip CPL and the side SH3 of the semiconductor chip CPH face each other. Note that, in plan view, the SL1 of the semiconductor chip CPL is parallel to the side SH3 of the semiconductor chip CPH. In addition, in plan view, the side SC4 of the semiconductor chip CPC and the side SH3 of the semiconductor chip CPH face each other. Note that, in plan view, the side SC4 of the semiconductor chip CPC is inclined to the side SH3 of the semiconductor chip CPH.

The front surface of the semiconductor chip CPH has a plurality of pads PH1, a plurality of pads PH2, and a plurality of pads PH3 formed thereon. The front surface of the semiconductor chip CPL has a plurality of pads PL1, a plurality of pads PL2, and a plurality of pads PL3 formed thereon. The front surface of the semiconductor chip CPC has a plurality of pads PC1, a plurality of pads PC2, a plurality of pads PC3, and a plurality of pads PC4 formed thereon. Note that a “bonding pad,” a “bonding pad electrode”, a “pad electrode,” or an “electrode” are simply referred to as a “pad.”

Each of the pads PL1, PL2, and PL3 of the semiconductor chip CPL is electrically connected through an internal wire of the semiconductor chip CPL with a circuit (the above-described transmitting circuit TX1, receiving circuit RX2, and the like) formed in the semiconductor chip CPL.

Here, the pad PL1 of the semiconductor chip CPL is a pad electrically connected with the pad PC1 of the semiconductor chip CPC via the wire BW. Each pad PL1 of the semiconductor chip CPL is electrically connected with the transmitting circuit TX1 in the semiconductor chip CPL via the internal wire of the semiconductor chip CPL. In addition, the pad PL2 of the semiconductor chip CPL is a pad electrically connected with the pad PC2 of the semiconductor chip CPC via the wire BW. Each pad PL2 of the semiconductor chip CPL is electrically connected with the receiving circuit RX2 in the semiconductor chip CPL via the internal wire of the semiconductor chip CPL. In addition, the pad PL3 of the semiconductor chip CPL is a pad electrically connected with the lead LD2 via the wire BW. On the front surface of the semiconductor chip CPL, the plurality of pads PL1 and PL2 is arranged along the side SL2 of the semiconductor chip CPL, and the plurality of pads PL3 is arranged along the side SL3 of the semiconductor chip CPL.

Each of the pads PH1, PH2, and PH3 of the 41 semiconductor chip CPH is electrically connected with the circuit (the receiving circuit RX1, the transmitting circuit TX2, the drive circuit DR, and the like) formed in the semiconductor chip CPH via an internal wire of the semiconductor chip CPH.

Here, the pad PH1 of the semiconductor chip CPH is a pad electrically connected with the pad PC3 of the semiconductor chip CPC via the wire BW. The pad PH1 of the semiconductor chip CPH is electrically connected with the receiving circuit RX1 of the semiconductor chip CPH via the internal wire of the semiconductor chip CPH. In addition, the pad PH2 of the semiconductor chip CPH is a pad electrically connected with the pad PC4 of the semiconductor chip CPC via the wire BW. The pad PH2 of the semiconductor chip CPH is electrically connected with the transmitting circuit TX2 in the semiconductor chip CPH via the internal wire of the semiconductor chip CPH. In addition, the pad PH3 of the semiconductor chip CPH is a pad electrically connected with the lead LD1 via the wire BW. On the front surface of the semiconductor chip CPH, the plurality of pads PH1 and PH2 is arranged along the side SH3 of the semiconductor chip CPH, and the plurality of pads PH3 is arranged along the side SH1 of the semiconductor chip CPH.

The pad PC1 of semiconductor chip CPC is a pad electrically connected with the coil L1a formed in the semiconductor chip CPC. In addition, the pad PC2 of the semiconductor chip CPC is a pad electrically connected with the coil L2a formed in the semiconductor chip CPC. In addition, the pad PC3 of the semiconductor chip CPC is a pad electrically connected with the coil L1b formed in the semiconductor chip CPC. In addition, the pad PC4 of the semiconductor chip CPC is a pad electrically connected with the coil L2b formed in the semiconductor chip CPC. On the front surface of the semiconductor chip CPC, the plurality of pads PC1 and PC2 is arranged along the side SC3 of the semiconductor chip CPC, and the plurality of pads PC3 and PC4 is arranged along the side SC1 of the semiconductor chip CPC.

Each of the plurality of pads PL1 of the semiconductor chip CPL and each of the plurality of pads PC1 of the semiconductor chip CPC are electrically connected with each other via a corresponding wire BW. More specifically, one end of each of the wires BW is connected with each of the pads PL1 of the semiconductor chip CPL, and the other end of each of the wire BW is connected with each of the pads PC1 of the semiconductor chip CPC. In addition, each of the plurality of pads PL2 of the semiconductor chip CPL and each of the plurality of pads PC2 of the semiconductor chip CPC are electrically connected with each other with a corresponding wire BW. More specifically, one end of each of the wires BW is connected with each of the pads PL2 of the semiconductor chip CPL, and the other end of each of the wires BW is connected with each of the pads PC2 of the semiconductor chip CPC.

Each of the plurality of pads PH1 of the semiconductor chip CPH and each of the plurality of pads PC3 of the semiconductor chip CPC are electrically connected with each other via a corresponding wire BW. More specifically, one end of each of the wires BW is connected with each of the pads PH1 of the semiconductor chip CPH, and the other end of each of the wires BW is connected with each of the pads PC3 of the semiconductor chip CPC. In addition, each of the plurality of pads PH2 of the semiconductor chip CPH and each of the plurality of pads PC4 of the semiconductor chip CPC are electrically connected with each other via a corresponding wire BW. More specifically, one end of each of the wires BW is connected with each of the pads PH2 of the semiconductor chip CPH, and the other end of each of the wires BW is connected with each of the pads PC4 of the semiconductor chip CPC.

In addition, each of the plurality of pads PL3 of the semiconductor chip CPL and each of the plurality of leads LD2 are electrically connected with each other via a corresponding wire BW. More specifically, one end of each of the wires BW is connected with each of the pads PL3 of the semiconductor chip CPL, and the other end of each of the wires BW is connected with each inner lead portion of the leads LD2.

In addition, each of the plurality of pads PH3 of the semiconductor chip CPH and each of the plurality of leads LD1 are electrically connected with each other via a corresponding wire BW. More specifically, one end of each of the wires BW is connected with each of the pads PH3 of the semiconductor chip CPH, and the other end of each of the wires BW is connected with each inner lead portion of the leads LD1.

The wire (bonding wire) BW is a conductive wire. The wire BW is formed of, in particular, a metal, and a gold (Au) wire, a copper (Cu) wire, an aluminum (Al) wire, or the like can preferably be used. The wire BW is sealed in the sealing portion MR and is not exposed from the sealing portion MR. At each of the leads LD, a connection portion of the wire BW is the inner lead portion positioned in the sealing portion MR.

At the time of using the semiconductor device PKG, the semiconductor chip CPL in the semiconductor device PKG is electrically connected with a circuit (more specifically, the above-described control circuit CC) outside the semiconductor device PKG via the wire BW (more specifically, the wire BW electrically connecting the pad PL3 and the lead LD2), the lead LD2, and the like. In addition, at the time of using the semiconductor device PKG, the semiconductor chip CPH in the semiconductor device PKG is electrically connected with a circuit (more specifically, the inverter circuit including the power transistors TS1 and TS2) outside the semiconductor device PKG via the wire BW (more specifically, the wire BW electrically connecting the pad PH3 and the lead LD1), the lead LD1, and the like. The drive circuit DR formed in the semiconductor chip CPH is electrically connected with the receiving circuit RX1 and transmitting circuit TX2 in the semiconductor chip CPH via the internal wire and the like of the semiconductor chip CPH. In addition, at the time of using the semiconductor device PKG, the drive circuit DR formed in the semiconductor chip CPH is electrically connected with a circuit (more specifically, the inverter circuit including the power transistors TS1 and TS2) outside the semiconductor device PKG via the wire BW (more specifically, the wire BW electrically connecting the pad PH3 and the lead LD1), the lead LD1, and the like. The power supply potential V1 supplied to the inverter circuit including the power transistors TS1 and TS2 is higher than the power supply potential V2 supplied to the control circuit CC.

### Manufacturing Process of Semiconductor Device

Next, a manufacturing process (assembling process) of the semiconductor device PKG of the present embodiment will simply be described.

In order to manufacture the semiconductor device PKG, a lead frame that has the die pads DPH and DPL and the plurality of leads LD in an integrated manner and the semiconductor chips CPC, CPH, and CPL are prepared.

Then, the semiconductor chip CPH is mounted on the upper surface DPHa of the die pad DPH of the lead frame via the bonding material BDH. The semiconductor chip CPC is mounted on the upper surface DPLa of the die pad DPL via the bonding material BDC. The semiconductor chip CPL is mounted on the upper surface DPLa of the die pad DPL via the bonding material BDL. In this case, each of the semiconductor chips CPC, CPH, and CPL is mounted with the back surface facing the corresponding die pad. Then, the bonding materials BDC, BDH, and BDL are cured by a heat treatment or the like.

Next, a wire bonding step is performed. In the wire bonding step, electrical connection between the pad PL1 of the semiconductor chip CPL and the pad PC1 of the semiconductor chip CPC and electrical connection between the pad PL2 of the semiconductor chip CPL and the pad PC2 of the semiconductor chip CPC are established via the wires BW. In addition, electrical connection between the pad PH1 of the semiconductor chip CPH and the pad PC3 of the semiconductor chip CPC and electrical connection between the pad PH2 of the semiconductor chip CPH and the pad PC4 of the semiconductor chip CPC are established via the wires BW. In addition, electrical connection between the pad PH3 of the semiconductor chip CPH and the lead LD1 and electrical connection between the pad PL3 of the semiconductor chip CPL and the lead LD2 are established via the wires BW.

Next, resin sealing in a molding step (resin molding step) is performed, and the sealing portion MR which seals the die pads DPH and DPL, the semiconductor chips CPC, CPH, and CPL, the plurality of wires BW, and the inner lead portions of the plurality of leads LD is formed.

Next, a plating layer (not illustrated) is formed onto each of the outer lead portions of the leads LD exposed from the sealing portion MR, as needed. Thereafter, the lead LD is cut off at a predetermined position outside the sealing portion MR, to be separated from the frame of the lead frame.

Next, the outer lead portion of the lead LD protruding from the sealing portion MR is subjected to bending processing (lead processing or lead molding).

In this manner, the semiconductor device PKG illustrated in FIG. 2 through FIG. 9 is manufactured.

### Regarding Semiconductor Chip

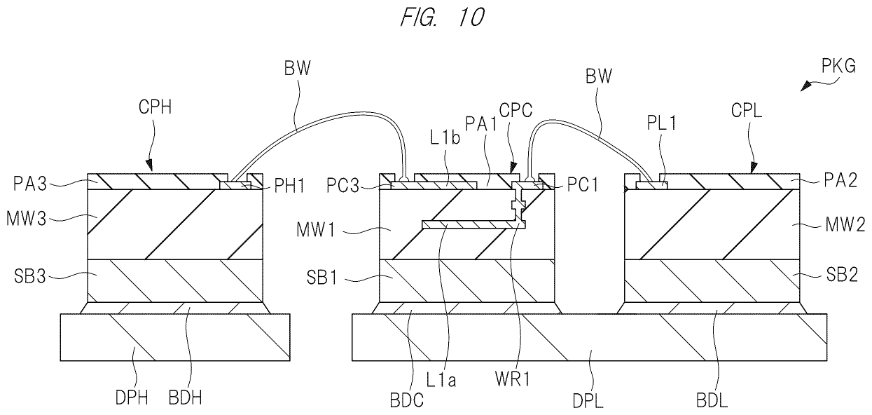

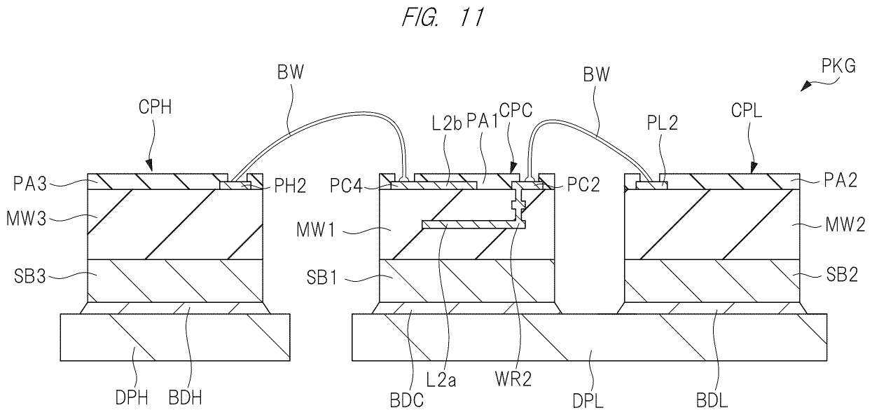

FIG. 10 and FIG. 11 are cross-sectional views schematically illustrating the semiconductor chips CPC, CPH, and CPL in the semiconductor device PKG. FIG. 10 corresponds to the cross-sectional view obtained by passing through the pad PL1, the pad PC1, the pad PC3, and the pad PH1. FIG. 11 corresponds to the cross-sectional view obtained by passing through the pad PL2, the pad PC2, the pad PC4, and the pad PH2. In FIG. 10 and FIG. 11, the die pads DPH and DPL, the semiconductor chips CPC, CPH, and CPL, and the wires BW are illustrated, but illustration of the sealing portion MR is omitted.

As illustrated in FIG. 10 and FIG. 11, the semiconductor chip CPC has a semiconductor substrate SB1, a multilayer wiring structure MW1 formed on the semiconductor substrate SB1, and a protective film PA1 formed on the multilayer wiring structure MW1. The multilayer wiring structure MW1 includes a plurality of interlayer insulation films and a plurality of wiring layers. The protective film PA1 is a protective film that is positioned in the uppermost layer of the semiconductor chip CPC. Each of the wires BW is connected with each of the pads PC1, PC2, PC3, and PC4 that is exposed in an opening of the protective film PA1.

The semiconductor chip CPC includes the coils L1a, L1b, L2a, and L2b, and the coils L1a, L1b, L2a, and L2b are formed of wiring layers included in the multilayer wiring structure MW1. The coils L1a and L1b are illustrated in FIG. 10, and the coils L2a and L2b are illustrated in FIG. 11. In addition, FIG. 10 and FIG. 11 illustrate wirings WR1 and WR2 in the semiconductor chip CPC.

Among the coils L1a and Lib constituting the transformer TR1, the coil L1a is electrically connected with the pad PL1 of the semiconductor chip CPL via the pad PC1 of the semiconductor chip CPC and the wire BW, and the coil L1b is electrically connected with the pad PH1 of the semiconductor chip CPH via the pad PC3 of the semiconductor chip CPC and the wire BW (see FIG. 10). In addition, among the coil L2a and L2b constituting the transformer TR2, the coil L2a is electrically connected with the pad PL2 of the semiconductor chip CPL via the pad PC2 of the semiconductor chip CPC and the wire BW, and the coil L2b is electrically connected with the pad PH2 of the semiconductor chip CPH via the pad PC4 of the semiconductor chip CPC and the wire BW (see FIG. 11).

In the semiconductor chip CPC, the coil L1a and the coil L1b are formed at such a position so as to overlap with each other in plan view, and the coil L2a and the coil L2b are formed at such a position so as to overlap with each other in plan view. In FIG. 10 and FIG. 11, in the semiconductor chip CPC, the coil L1a is formed below the coil L1b, and the coil L2a is formed below the coil L2b. The pad PC3 is connected with the coil L1b, the pad PC4 is connected with the coil L2b, the pad PC1 is connected with the coil L1a via the wiring WR1, and the pad PC2 is connected with the coil L2a via the wiring WR2. As an alternative mode, in the semiconductor chip CPC, the coil L1b may be formed below the coil L1a, and the coil L2b may be formed below the coil L2a. Each of the coils L1a, L1b, L2a, and L2b is formed in a spiral shaped conductive pattern (wiring pattern).

A semiconductor element (specifically, a transistor such as the above-described MOSFET) is not formed in the semiconductor chip CPC. In other words, the semiconductor substrate SB1 constituting the semiconductor chip CPC has no semiconductor element (specifically, a transistor such as the above-described MOSFET) formed therein.

The semiconductor chip CPL has a semiconductor substrate SB2, a multilayer wiring structure MW2 formed on the semiconductor substrate SB2, and a protective film PA2 formed on the multilayer wiring structure MW2. The multilayer wiring structure MW2 includes a plurality of interlayer insulation films and a plurality of wiring layers. The protective film PA2 is a protective film that is positioned in the uppermost layer of the semiconductor chip CPL. A plurality of semiconductor elements such as transistors (not illustrated) are formed in the semiconductor substrate SB2 constituting the semiconductor chip CPL. Each of the wires BW is connected with each of the pads PL1, PL2, and PL3 that is exposed in an opening of the protective film PA2.

The semiconductor chip CPH has a semiconductor substrate SB3, a multilayer wiring structure MW3 formed on the semiconductor substrate SB3, and a protective film PA3 formed on the multilayer wiring structure MW3. The multilayer wiring structure MW3 includes a plurality of interlayer insulation films and a plurality of wiring layers. The protective film PA3 is a protective film that is positioned in the uppermost layer of the semiconductor chip CPH. A plurality of semiconductor elements such as transistors (not illustrated) are formed in the semiconductor substrate SB3 constituting the semiconductor chip CPH. Each of the wires BW is connected with each of the pads PH1, PH2, and PH3 that is exposed in an opening of the protective film PA3.

### Regarding Background of Study

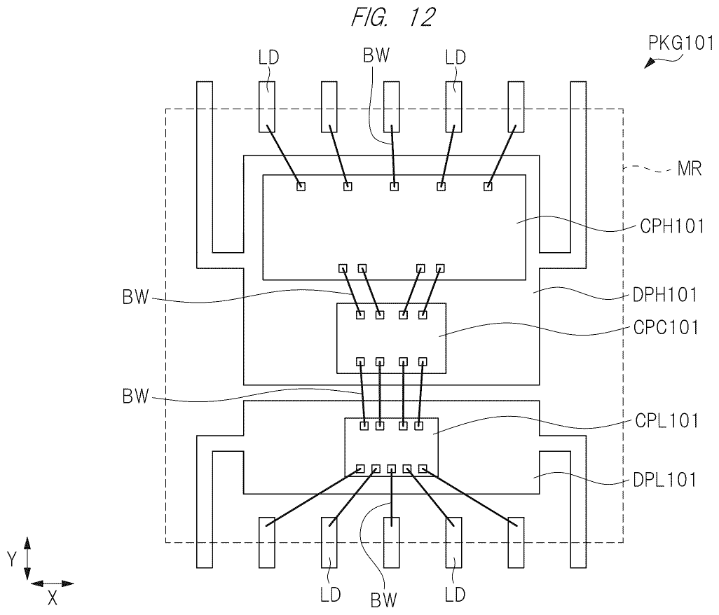

FIG. 12 is a plan perspective view of the semiconductor device PKG101 according to a first study example which the present inventors have studied and corresponds to the above-described FIG. 3.

The semiconductor device PKG101 according to the first study example illustrated in FIG. 12 has a die pad DPH101 and a die pad DPL101 in place of the die pads DPH and DPL, respectively. Then, a semiconductor chip CPH101 corresponding to the semiconductor chip CPH and the semiconductor chip CPC101 corresponding to the semiconductor chip CPC are mounted on the die pad DPH101, and the semiconductor chip CPL101 corresponding to the semiconductor chip CPL is mounted on the die pad DPL101.

In the case of the semiconductor device PKG101 according to the first study example, as illustrated in FIG. 12, the three semiconductor chips CPL101, CPC101, and CPH101 are arranged in a line in the Y direction. In this case, according to the study by the present inventors, it has been clear that the following problems may occur.

First, as described above, a semiconductor chip operating at a low voltage has a transmitting circuit and a receiving circuit formed therein, whereas a semiconductor chip operating at a high voltage has the transmitting circuit, the receiving circuit, and a drive circuit formed therein. Hence, it is difficult to make a plane size (plane area) of each of the semiconductor chips CPH and CPH101 for high voltage smaller than that of each of the semiconductor chips CPL and CPL101 for low voltage. In other words, it is possible to make the plane size (plane area) of each of the semiconductor chips CPL and CPL101 for low voltage larger than that of each of the semiconductor chips CPH and CPH101 for high voltage. In addition, in recent years, along with higher functionality of the semiconductor device and increase in current flowing through a circuit to be used (an inverter circuit and the like), the plane size of the semiconductor chips CPH and CPH101 for high voltage tends to increase, compared to the plane size of each of the semiconductor chips CPL and CPL101 for low voltage.

Moreover, as described above, a semiconductor chip in which a plurality of transformers are formed has no transmitting circuit, receiving circuit, or drive circuit formed therein. Hence, it is possible to make the plane size (plane area) of each of the semiconductor chips CPC and CPC101 smaller than that of each of the semiconductor chips CPH and CPH101 for high voltage.

As in the semiconductor device PKG101 of the first study example, in a case in which the three semiconductor chips CPL101, CPC101, and CPH101 are arranged in a line in the Y direction, the size of the semiconductor device PKG101 in the Y direction becomes large. This causes increase in size of the semiconductor device PKG101. In order to decrease the size of the semiconductor device PKG101 in the Y direction, it is effective to make the size of each of the semiconductor chips CPL101, CPC101, and CPH101 in the Y direction small. However, when the size of each of the semiconductor chips CPL101, CPC101, and CPH101 in the Y direction is made small, along with the size reduction, the size of each of the semiconductor chips CPL101, CPC101, and CPH101 in the X direction is required to be enlarged, an aspect ratio (a ratio of a length of a long side to a length of a short side) of each of the semiconductor chips CPL101, CPC101, and CPH101 becomes large. When the aspect ratio of each of the semiconductor chips becomes large, for example, a crack is likely to occur in the semiconductor chip at a time of obtaining a semiconductor chip as a result of cutting a semiconductor wafer or at a time of transferring a semiconductor chip. This reduces the manufacturing yield of the semiconductor chip and the manufacturing yield of a semiconductor device incorporating a semiconductor chip.

In addition, due to the above-described reasons, as illustrated in FIG. 12, the plane size of each of the semiconductor chip CPL101 and the semiconductor chip CPC101 is smaller than that of the semiconductor chip CPH101. Hence, in a case in which the size of each of the three semiconductor chips CPL101, CPC101, and CPH101 in the X direction is the same with each other, the aspect ratio of the semiconductor chip CPL101 and the aspect ratio of the semiconductor chip CPC101 become considerably larger than that of the semiconductor chip CPH101. Hence, as for the semiconductor chips CPL101 and CPC101 each having the large aspect ratio, the problem regarding the above-described crack is especially concerned.

### Regarding Main Features and Effects

One main feature of the semiconductor device PKG according to the present embodiment is that, as illustrated in FIG. 4, the semiconductor chip CPH is mounted (disposed) on the die pad DPH, and the semiconductor chip CPC and the semiconductor chip CPL are mounted (disposed) on the die pad DPL positioned adjacent to the die pad DPH in the Y direction, so that the semiconductor chip CPC and the semiconductor chip CPL are adjacent to each other in the X direction orthogonal to the Y direction. Note that, as described above, the length of each of the sides SL1, SL2, SL3, and SL4 of the semiconductor chip CPL is smaller than the length of the side SH3 of the semiconductor chip CPH. In addition, the length of each of the sides SC1, SC2, SC3, and SC4 of the semiconductor chip CPC is also smaller than the length of the side SH3 of the semiconductor chip CPH. Hence, even if the aspect ratio of each of the semiconductor chip CPC and the semiconductor chip CPL is not made larger, adopting the above-described layout enables the size of the semiconductor device PKG according to the present embodiment in the Y direction to be reduced. Hence, it is possible to achieve size reduction of the semiconductor device PKG. In addition, even if the aspect ratio of each of the semiconductor chip CPC and the semiconductor chip CPL is not made large, reduction in size of the semiconductor device PKG can be achieved, so that it is also possible to avoid the risk of occurrence of cracks in the semiconductor chips CPL and CPC at, for example, a time of obtaining a semiconductor chip as a result of cutting a semiconductor wafer or a time of transferring a semiconductor chip. Hence, the manufacturing yield of the semiconductor chips CPL and CPC and the manufacturing yield of the semiconductor device PKG can be enhanced. As a result, it is possible to reduce the manufacturing costs of the semiconductor device PKG.

Another main feature of the semiconductor device PKG according to the present embodiment is that the plurality of pads PL1 and PL2 is arranged along the side SL2 of the semiconductor chip CPL on the front surface of the semiconductor chip CPL, the plurality of pads PH1 and PH2 is arranged along the side SH3 of the semiconductor chip CPH on the front surface of the semiconductor chip CPH, the plurality of pads PC1 and PC2 is arranged along the side SC3 of the semiconductor chip CPC on the front surface of the semiconductor chip CPC, and the plurality of pads PC3 and PC4 is arranged along the side SC1 of the semiconductor chip CPC on the front surface of the semiconductor chip CPC. In the semiconductor chip CPC, the side SC1 and the side SC3 are positioned facing each other. Then, the semiconductor chip CPL and the semiconductor chip CPC are arranged along the side SH3 of the semiconductor chip CPH such that, in plan view, the side SC3 of the semiconductor chip CPC faces the side SL2 of the semiconductor chip CPL and such that the side SC1 of the semiconductor chip CPC faces the side SH3 of the semiconductor chip CPH. Accordingly, it is possible to enhance the manufacturing yield of the semiconductor device PKG. In addition, performance of the semiconductor device PKG can be enhanced.

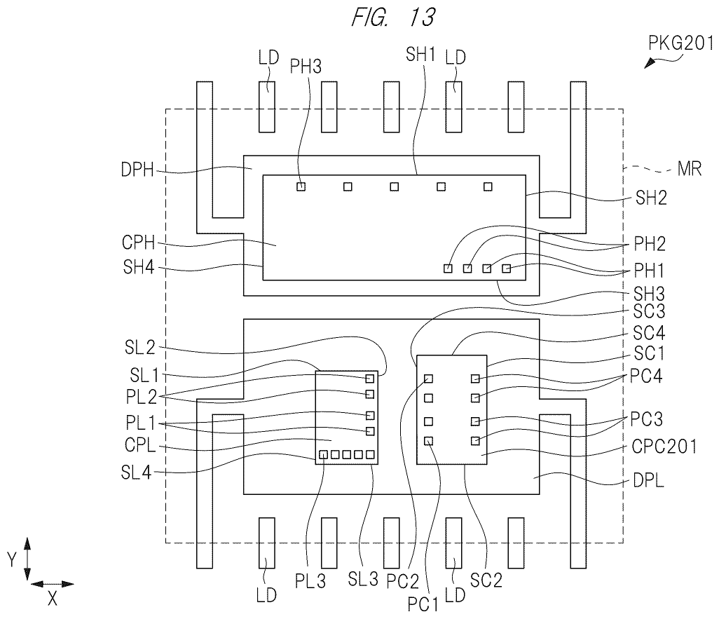

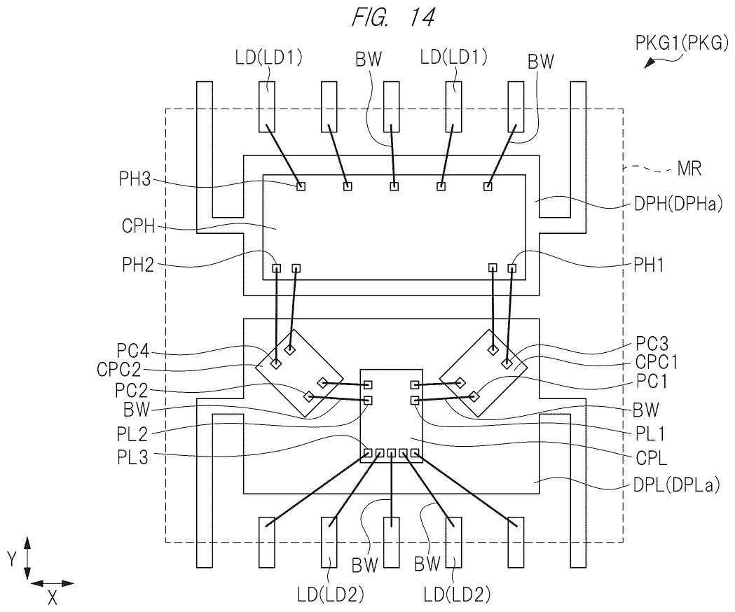

Here, FIG. 13 is a plan perspective view of a semiconductor device PKG201 according to a second study example that has been studied by the present inventors. FIG. 13 corresponds to the above-described FIG. 4, in which no wire BW is illustrated.

In the semiconductor device PKG201 according to the second study example illustrated in FIG. 13, the semiconductor chip CPH is mounted on the die pad DPH, and the semiconductor chip CPL and the semiconductor chip CPC201 are disposed on the die pad DPL, so that the semiconductor chip CPL and the semiconductor chip CPC201 are adjacent to each other in the X direction. Here, although the semiconductor chip CPC201 according to the second study example has the same structure as that of the semiconductor chip CPC according to the present embodiment, the direction of the layout of the semiconductor chip CPC201 is different from the direction of the layout of the semiconductor chip CPC according to the present embodiment. Moreover, as with the semiconductor chip CPC, the semiconductor chip CPC201 incorporates the transformers TR1 and TR2, the four sides SC1, SC2, SC3, and SC4, and the plurality of pads PC1, PC2, PC3, and PC4. The layout position of each of the pads PC1, PC2, PC3, and PC4 in the semiconductor chip CPC201 is the same as the layout position of each of the pads PC1, PC2, PC3, and PC4 of the semiconductor chip CPC. Hence, on the front surface of the semiconductor chip CPC201, the plurality of pads PC3 and PC4 is arranged along the side SC1 of the semiconductor chip CPC201, and the plurality of pads PC1 and PC2 is arranged along the side SC3 of the semiconductor chip CPC201.

In the case of the semiconductor device PKG201 according to the second study example illustrated in FIG. 13, the semiconductor chip CPC201 is disposed such that, in plan view, the sides SC1 and SC3 of the semiconductor chip CPC201 are parallel to the Y direction and the sides SC2 and SC4 of the semiconductor chip CPC201 are parallel to the X direction. Accordingly, in plan view, the side SC3 of the semiconductor chip CPC201 and the side SL2 of the semiconductor chip CPL face each other, so that the plurality of pads PC1 and PC2 arranged along the side SC3 on the front surface of the semiconductor chip CPC201 can be connected with the plurality of pads PL1 and PL2 of the semiconductor chip CPL via the plurality of wires, respectively.

However, in the case of the semiconductor device PKG201 according to the second study example illustrated in FIG. 13, in plan view, the side SC1 of the semiconductor chip CPC201 does not face the side SH3 of the semiconductor chip CPH, and the side SC4 of the semiconductor chip CPC201 faces the side SH3 of the semiconductor chip CPH. Accordingly, it is difficult to connect the plurality of pads PC3 and PC4 arranged along the side SC1 on the front surface of the semiconductor chip CPC201 with the plurality of pads PH1 and PH2 of the semiconductor chip CPH via the plurality of wires, respectively. In a case in which the plurality of pads PC3 and PC4 of the semiconductor chip CPC201 and the plurality of pads PH1 and PH2 of the semiconductor chip CPH are connected with each other via the plurality of wires, short circuiting between these plurality of wires is concerned. Hence, even if the semiconductor device PKG201 is manufactured, the manufacturing yield is low.

In contrast, in the case of the semiconductor device PKG according to the present embodiment, in plan view, the side SC3 of the semiconductor chip CPC faces the side SL2 of the semiconductor chip CPL, and the side SC1 of the semiconductor chip CPC faces the side SH3 of the semiconductor chip CPH. In plan view, the side SC3 of the semiconductor chip CPC and the side SL2 of the semiconductor chip CPL face each other, so that the plurality of pads PC1 and PC2 arranged along the side SC3 on the front surface of the semiconductor chip CPC can easily and appropriately be connected with the plurality of pads PL1 and PL2 of the semiconductor chip CPL via the plurality of wires BW, respectively. Hence, when the plurality of pads PC1 and PC2 of the semiconductor chip CPC and the plurality of pads PL1 and PL2 of the semiconductor chip CPL are connected with each other via the plurality of wires BW, it is possible to appropriately prevent short circuiting between the plurality of wires BW. In addition, in plan view, the side SC1 of the semiconductor chip CPC and the side SH3 of the semiconductor chip CPH face each other, so that the plurality of pads PC3 and PC4 arranged along the side SC1 on the front surface of the semiconductor chip CPC can easily and appropriately be connected with the plurality of pads PH1 and PH2 of the semiconductor chip CPH via the plurality of wires BW, respectively. Hence, when the plurality of pads PC3 and PC4 of the semiconductor chip CPC and the plurality of pads PH1 and PH2 of the semiconductor chip CPH are connected with each other via the plurality of wires BW, it is possible to easily and appropriately prevent short circuiting between these plurality of wires BW. As a result, it is possible to enhance the manufacturing yield of the semiconductor device PKG. Accordingly, it is possible to reduce the manufacturing costs of the semiconductor device PKG.

Here, a configuration in which the side SC3 of the semiconductor chip CPC faces the side SL2 of the semiconductor chip CPL and the side SC1 of the semiconductor chip CPC faces the side SH3 of the semiconductor chip CPH in plan view means that the side SC3 of the semiconductor chip CPC is inclined to the side SL2 of the semiconductor chip CPL and the side SC1 of the semiconductor chip CPC is inclined to the side SH3 of the semiconductor chip CPH. This is because, in a case in which the side SC3 of the semiconductor chip CPC is parallel or vertical to the side SL2 of the semiconductor chip CPL and the side SC1 of the semiconductor chip CPC is parallel or vertical to the side SH3 of the semiconductor chip CPH, the configuration in which the side SC3 of the semiconductor chip CPC faces the side SL2 of the semiconductor chip CPL is incompatible with the configuration in which the side SC1 of the semiconductor chip CPC faces the side SH3 of the semiconductor chip CPH.

An inclination angle B1 of the side SC3 of the semiconductor chip CPC (specifically, an inclination angle of the side SC3 of the semiconductor chip CPC to the Y direction) to the side SL2 of the semiconductor chip CPL is preferably in a range of 40 degrees to 50 degrees, and is most preferably 45 degrees. In addition, an inclination angle B2 of the side SC1 of the semiconductor chip CPC (specifically, an inclination angle of the side SC1 of the semiconductor chip CPC to the X direction) to the side SH3 of the semiconductor chip CPH is preferably in a range of 40 degrees to 50 degrees, and is most preferably 45 degrees. Accordingly, easily and appropriately connecting the plurality of pads PC1 and PC2 of the semiconductor chip CPC with the plurality of pads PL1 and PL2 of the semiconductor chip CPL, respectively, via the plurality of wires BW is likely to be made compatible with easily and appropriately connecting the plurality of pads PC3 and PC4 of the semiconductor chip CPC with the plurality of pads PH1 and PH2 of the semiconductor chip CPH, respectively, via the plurality of wires BW.

In addition, according to the present embodiment, the semiconductor chip CPC is mounted not on the die pad DPH but on the die pad DPL. Compared to the die pad DPH on which the semiconductor chip CPH is mounted, voltage variation hardly occurs in the die pad DPL on which the semiconductor chip CPL is mounted. This is because the semiconductor chip CPL is electrically connected via the wire BW, the lead LD2, and the like with a low voltage region, and the semiconductor chip CPH is electrically connected via the wire BW, the lead LD1, and the like with a high voltage region. Accordingly, compared to a case in which the semiconductor chip CPC is mounted on the die pad DPH, a case in which the semiconductor chip CPC is mounted on the die pad DPL hardly generates voltage variation in the die pad DPL, so that generation of noise in a signal transmitted through the transformers TR1 and TR2 in the semiconductor chip CPC can be prevented. As a result, performance of the semiconductor device PKG can be enhanced.

According to the present embodiment, the two transformers TR1 and TR2 are incorporated in the semiconductor chip CPC. As a modification example, a case in which one transformer is incorporated in the semiconductor chip CPC may be possible. For example, in the semiconductor device PKG, a case in which the transformer TR2 is not incorporated and the transformer TR1 is incorporated in the semiconductor chip CPC, the semiconductor chip CPC has the pads PC1 and PC3 but does not have the pad PC2 and PC4, the semiconductor chip CPL has the pads PL1 and PL3 but does not have the pad PL2, and the semiconductor chip CPH has the pads PH1 and PH3 but does not have the pad PH2.

In addition, according to the present embodiment, an example in which the number of pads electrically connected with each of the coils L1a, Lib, L2a, and L2b is two each in the semiconductor chip CPC is illustrated. As a modification example, a case in which the number of pads electrically connected with each of the coils L1a, L1b, L2a, and L2b is three or more each in the semiconductor chip CPC may also be possible. For example, in a case in which each coil is of a differential type, the number of pads electrically connected with the coil is three. In this case, the number of pads PC1, the number of pads PC2, the number of pads PC3, and the number of pads PC4 are three each. The number of pads PL1 is the same as the number of pads PC1, the number of pads PL2 is the same as the number of pads PC2, the number of pads PH1 is the same as the number of pads PC3, and the number of pads PH2 is the same as the number of pads PC4. This is also the same in the following second embodiment through the sixth embodiment.

### Second Embodiment

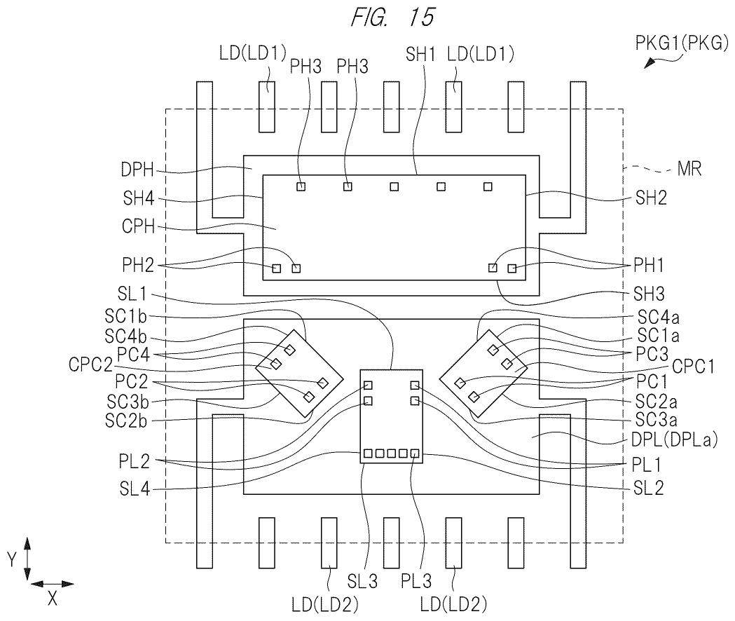

FIG. 14 and FIG. 15 are plan perspective views of the semiconductor device PKG according to the second embodiment (hereinafter, referred to as a semiconductor device PKG1). FIG. 14 corresponds to the above-described FIG. 3, and FIG. 15 corresponds to the above-described FIG. 4.

In the following description, with reference to FIG. 14 and FIG. 15, regarding a structure of the semiconductor device PKG1 according to the second embodiment, differences from the semiconductor device PKG according to the first embodiment will mainly be described. As for points that the semiconductor device PKG1 according to the second embodiment has in common with the semiconductor device PKG according to the first embodiment, redundant descriptions thereof are omitted as appropriate.

As illustrated in FIG. 14 and FIG. 15, the semiconductor device PKG1 according to the second embodiment has two semiconductor chips CPC1 and CPC2 in place of the semiconductor chip CPC. The semiconductor chips CPC1 and CPC2 are sealed with the sealing portion MR. Among the transformers TR1 and TR2, the transformer TR1 (coils L1a and L1b) is formed in the semiconductor chip CPC1, and the transformer TR2 (coils L2a and L2b) is formed in the semiconductor chip CPC2. Hence, among the pads PC1, PC2, PC3, and PC4, the pads PC1 and PC3 are formed in the semiconductor chip CPC1, and the pads PC2 and PC4 are formed in the semiconductor chip CPC2.

In the semiconductor device PKG1 according to the second embodiment, the three semiconductor chips CPL, CPC1, and CP2 are each mounted on the die pad DPL via a bonding material, and the one semiconductor chip CPH is mounted on the die pad DPH via a bonding material.

Each of the semiconductor chips CPC1 and CPC2 has a front surface that is one main surface, and a back surface that is the other main surface opposite to the front surface. The semiconductor chips CPC1 and CPC2 each have a quadrangular planar shape, and preferably have a rectangular shape. Accordingly, in plan view, the semiconductor chip CPC1 has four sides SC1a, SC2a, SC3a, and SC4a, and the semiconductor chip CPC2 has four sides SC1b, SC2b, SC3b, and SC4b.

Among the four sides SC1a, SC2a, SC3a, and SC4a of the semiconductor chip CPC1, the side SC1a and the side SC3a are positioned to be opposite to each other, and the side SC2a and the side SC4a are positioned to be opposite to each other. The side SC1a intersects with the sides SC2a and SC4a, and the side SC3a intersects with the sides SC2a and SC4a. In addition, among the four sides SC1b, SC2b, SC3b, and SC4b of the semiconductor chip CPC2, the side SC1b and the side SC3b are positioned to be opposite to each other, and the side SC2b and the side SC4b are positioned to be opposite to each other. The side SC1b intersects with the sides SC2b and SC4b, and the side SC3b intersects with the sides SC2b and SC4b. Each of the front surfaces and the back surfaces of the semiconductor chips CPC1 and CPC2 is substantially parallel to both the X direction and the Y direction.

In plan view, the semiconductor chip CPC1 is adjacent to the semiconductor chip CPL in the X direction, the semiconductor chip CPC2 is adjacent to the semiconductor chip CPL in the X direction, and the semiconductor chip CPL is disposed between the semiconductor chip CPC1 and the semiconductor chip CPC2 in the X direction. Accordingly, the semiconductor chip CPC1, the semiconductor chip CPL, and the semiconductor chip CPC2 are arranged along the side SH3 of the semiconductor chip CPH. Each of the semiconductor chips CPC1, CPC2, and CPL is adjacent to the semiconductor chip CPH in the Y direction.

In addition, according to the second embodiment, in plan view, the side SC3a of the semiconductor chip CPC1 and the side SL2 of the semiconductor chip CPL face each other, and the side SC1a of the semiconductor chip CPC1 and the side SH3 of the semiconductor chip CPH face each other. Note that, in plan view, the side SC3a of the semiconductor chip CPC1 is inclined to the side SL2 of the semiconductor chip CPL, and the side SC1a of the semiconductor chip CPC1 is inclined to the side SH3 of the semiconductor chip CPH. In addition, in plan view, the side SC2b of the semiconductor chip CPC2 faces the side SL4 of the semiconductor chip CPL, and the side SC4b of the semiconductor chip CPC2 faces the side SH3 of the semiconductor chip CPH. Note that, in plan view, the side SC2b of the semiconductor chip CPC2 is inclined to the side SL4 of the semiconductor chip CPL, and the side SC4b of the semiconductor chip CPC2 is inclined to the side SH3 of the semiconductor chip CPH.

The sides SC1a, SC2a, SC3a, and SC4a of the semiconductor chip CPC1 and the sides SC1b, SC2b, SC3b, and SC4b of the semiconductor chip CPC2 are each inclined to the X direction and to the Y direction. Hence, the sides SC1a, SC2a, SC3a, and SC4a of the semiconductor chip CPC1 and the sides SC1b, SC2b, SC3b, and SC4b of the semiconductor chip CPC2 are not parallel to either the X direction or the Y direction. An inclination angle of each of the sides SC1a, SC2a, SC3a, and SC4a of the semiconductor chip CPC1 and the sides SC1b, SC2b, SC3b, and SC4b of the semiconductor chip CPC2 to the X direction is preferably in a range of 40 degrees to 50 degrees, and is most preferably 45 degrees.

According to the second embodiment, on the front surface of the semiconductor chip CPL, the plurality of pads PL1 is arranged along the side SL2 of the semiconductor chip CPL, the plurality of pads PL2 is arranged along the side SL4 of the semiconductor chip CPL, and the plurality of pads PL3 is arranged along the side SL3 of the semiconductor chip CPL. In addition, on the front surface of the semiconductor chip CPH, the plurality of pads PH1 is arranged along the side SH3 of the semiconductor chip CPH, the plurality of pads PH2 is arranged along the side SH3 of the semiconductor chip CPH, and the plurality of pads PH3 is arranged along the side SH1 of the semiconductor chip CPH. Note that the plurality of pads PH1 is arranged close to the side SH2 of the semiconductor chip CPH, and the plurality of pads PH2 is arranged close to the side SH4 of the semiconductor chip CPH. In addition, on the front surface of the semiconductor chip CPC1, the plurality of pads PC1 is arranged along the side SC3a of the semiconductor chip CPC1, and the plurality of pads PC3 is arranged along the side SC1a of the semiconductor chip CPC1. In addition, on the front surface of the semiconductor chip CPC2, the plurality of pads PC2 is arranged along the side SC2b of the semiconductor chip CPC2, and the plurality of pads PC4 is arranged along the side SC4b of the semiconductor chip CPC2. In plan view, among four corner portions of the semiconductor chip CPC1, a distance between a corner portion formed by the sides SC4a and SC1a and the semiconductor chip CPH (distance in the Y direction) is smaller than a distance between each of the other corner portions of the semiconductor chip CPC1 and the semiconductor chip CPH (distance in the Y direction). In addition, in plan view, among four corner portions of the semiconductor chip CPC2, a distance between a corner portion formed by the sides SC4b and SC1b and the semiconductor chip CPH (distance in the Y direction) is smaller than a distance between each of the other corner portions of the semiconductor chip CPC2 and the semiconductor chip CPH (distance in the Y direction).

Next, effects of the semiconductor device PKG1 according to the second embodiment will be described.

In the semiconductor device PKG1 according to the second embodiment, the semiconductor chip CPH is disposed on the die pad DPH, and the semiconductor chips CPC1, CPC2, and CPL are disposed on the die pad DPL that is adjacent to the die pad DPH in the Y direction. Also, the semiconductor chip CPC1 and the semiconductor chip CPL are adjacent to each other in the X direction, the semiconductor chip CPC2 and the semiconductor chip CPL are adjacent to each other in the X direction, and the semiconductor chip CPL is positioned between the semiconductor chip CPC1 and the semiconductor chip CPC2 in the X direction. With this layout, even if the aspect ratio of each of the semiconductor chips CPC1, CPC2, and CPL is not made large, the size of the semiconductor device PKG according to the present embodiment in the Y direction can be made small. Hence, reduction in size of the semiconductor device PKG1 can be achieved. In addition, since the aspect ratio of each of the semiconductor chips CPC1, CPC2, and CPL can be suppressed, a risk of occurrence of cracks in the semiconductor chips CPL, CPC1, and CPC2 can be prevented at, for example, a time of obtaining a semiconductor chip as a result of cutting a semiconductor wafer, a time of transferring a semiconductor chip, and the like. Hence, the manufacturing yield of the semiconductor chips CPL, CPC1, and CPC2 and the manufacturing yield of the semiconductor device PKG1 can be enhanced.

In addition, in the semiconductor device PKG1 according to the second embodiment, in plan view, the side SC1a of the semiconductor chip CPC1 and the side SH3 of the semiconductor chip CPH face each other. Hence, the plurality of pads PC3 disposed along the side SC1a on the front surface of the semiconductor chip CPC1 can easily and appropriately be connected with the plurality of pads PH1 of the semiconductor chip CPH via the plurality of wires BW. In addition, in plan view, the side SC3a of the semiconductor chip CPC1 and the side SL2 of the semiconductor chip CPL face each other. Hence, the plurality of pads PC1 arranged along the side SC3a on the front surface of the semiconductor chip CPC1 can easily and appropriately be connected with the plurality of pads PL1 of the semiconductor chip CPL via the plurality of wires BW. In addition, in plan view, the side SC4b of the semiconductor chip CPC2 and the side SH3 of the semiconductor chip CPH face each other. Hence, the plurality of pads PC4 arranged along the side SC4b on the front surface of the semiconductor chip CPC2 can easily and appropriately be connected with the plurality of pads PH2 of the semiconductor chip CPH via the plurality of wires BW. In addition, in plan view, the side SC2b of the semiconductor chip CPC2 and the side SL4 of the semiconductor chip CPL face each other. Hence, the plurality of pads PC2 arranged along the side SC2b on the front surface of the semiconductor chip CPC2 can easily and appropriately be connected with the plurality of pads PL2 of the semiconductor chip CPL via the plurality of wires BW. Hence, it is possible to appropriately prevent short circuiting between adjacent wires BW, so that the manufacturing yield of the semiconductor device PKG1 can be enhanced.

In addition, in the semiconductor device PKG1 of the second embodiment, the semiconductor chips CPC1 and CPC2 are mounted not on the die pad DPH but on the die pad DPL. Accordingly, compared to a case in which the semiconductor chips CPC1 and CPC2 are mounted on the die pad DPH, a case in which the semiconductor chips CPC1 and CPC2 are mounted on the die pad DPL hardly generates voltage variation in the die pad DPL, so that generation of noise in a signal transmitted through the transformers TR1 and TR2 in the respective semiconductor chips CPC1 and CPC2 can be prevented. As a result, performance of the semiconductor device PKG1 can be enhanced.

In addition, in the second embodiment, the transformer TR1 (coils L1a and L1b) is formed in the semiconductor chip CPC1, and the transformer TR2 (coil L2a and L2b) is formed in the semiconductor chip CPC2. Hence, a coupling noise between the transformer TR1 and the transformer TR2 can be reduced. Specifically, the signals transmitted through the transformer TR1 and the signals transmitted through the transformer TR2 are electromagnetically separated, so that they can be prevented from interfering with each other. Hence, performance of the semiconductor device PKG1 can further be enhanced.

In contrast, in the case of the first embodiment, since the transformer TR1 (coils L1a and L1b) and the transformer TR2 (coils L2a and L2b) are formed in the semiconductor chip CPC, the number of semiconductor chips included in the semiconductor device PKG can be reduced. Hence, the manufacturing costs of the semiconductor device PKG can be reduced.

### Third Embodiment

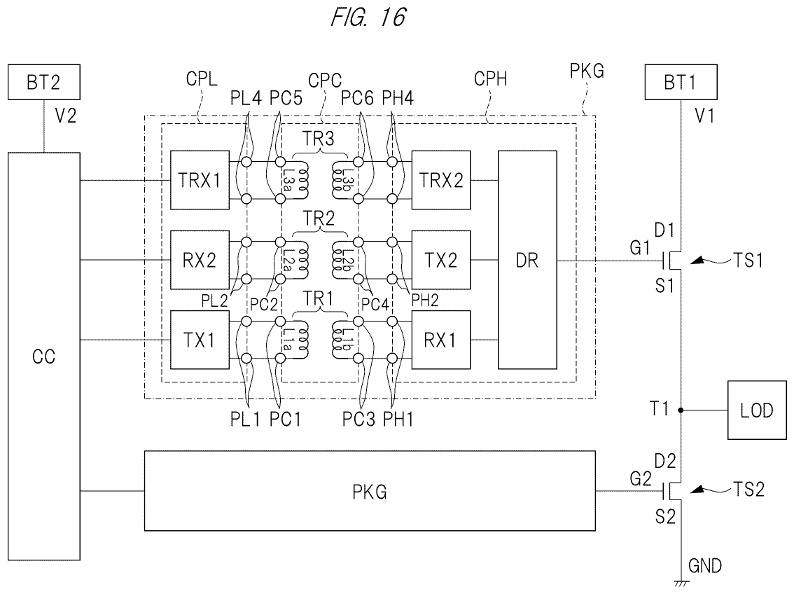

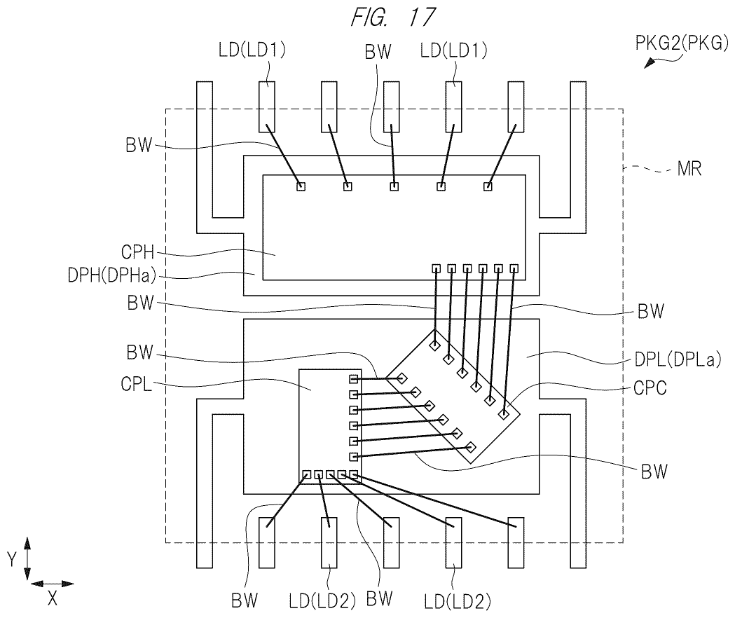

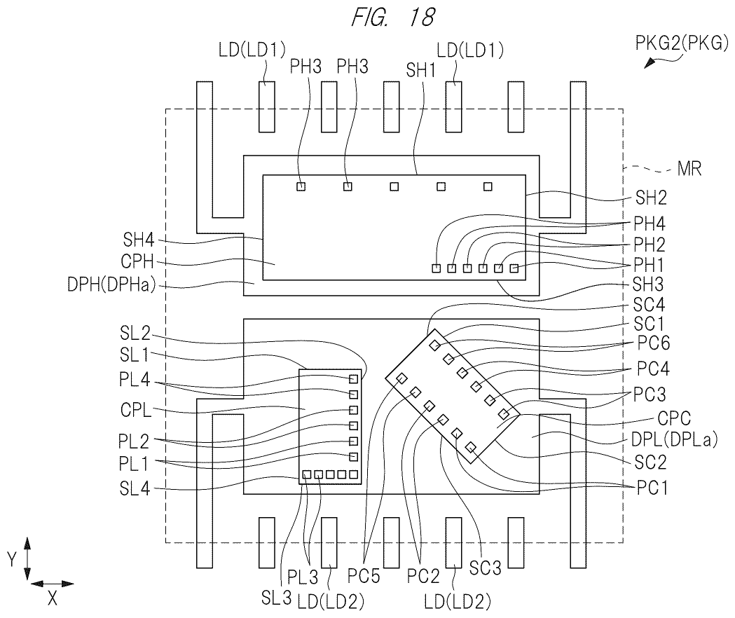

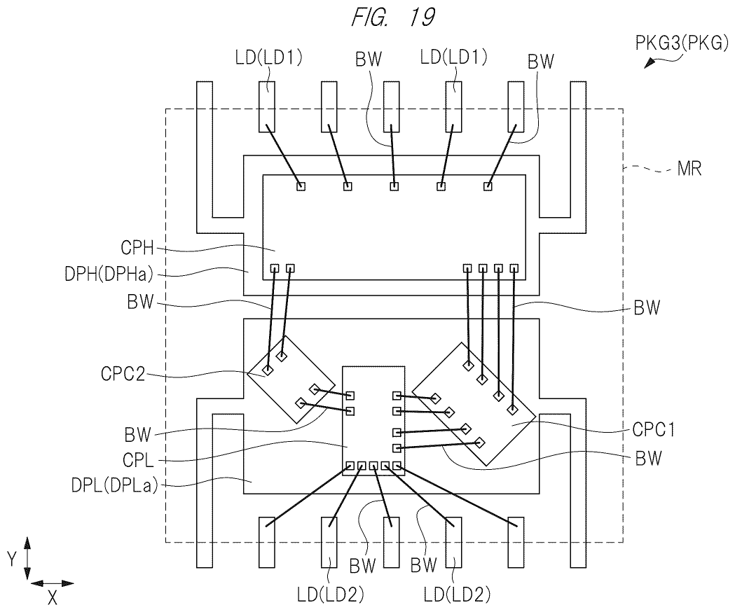

FIG. 16 is a circuit diagram illustrating an inverter circuit using the semiconductor device PKG according to the third embodiment (hereinafter, referred to as a semiconductor device PKG2) and corresponds to the above-described FIG. 1. FIG. 17 and FIG. 18 are plan perspective views illustrating the semiconductor device PKG2 according to the third embodiment. FIG. 17 corresponds to the above-described FIG. 3, and FIG. 18 corresponds to the above-described FIG. 4.

In the following description, with reference to FIG. 16 through FIG. 18, regarding a structure of the semiconductor device PKG2 according to the third embodiment, differences from the semiconductor device PKG according to the first embodiment will mainly be described. As for points that the semiconductor device PKG2 according to the third embodiment has in common with the semiconductor device PKG according to the first embodiment, redundant descriptions thereof are omitted as appropriate.

In the third embodiment, as illustrated in FIG. 16, the semiconductor chip CPC has the transformers TR1 and TR2 as well as a transformer TR3 including coils L3a and L3b magnetically coupled with each other formed therein. Accordingly, as illustrated in FIG. 17 and FIG. 18, the semiconductor chip CPC has the pads PC1, PC2, PC3, and PC4 as well as a plurality of pads PC5 which are each electrically connected with the coil L3a and a plurality of pads PC6 which are each electrically connected with the coil L3b. On the front surface of the semiconductor chip CPC, the plurality of pads PC1, PC2, and PC5 is arranged along the side SC3 of the semiconductor chip CPC, and the plurality of pads PC3, PC4, and PC6 is arranged along the side SC1 of the semiconductor chip CPC.

In addition, in the third embodiment, as illustrated in FIG. 16, the semiconductor chip CPL has not only the transmitting circuit TX1 and the receiving circuit RX2 but also a transmission and reception circuit TRX1 formed therein. In addition, the semiconductor chip CPH has not only the receiving circuit RX1, the transmitting circuit TX2, and the drive circuit DR but also a transmission and reception circuit TRX2 formed therein. The transmission and reception circuit TRX1 has a function as a transmitting circuit and a function as a receiving circuit. Similarly, the transmission and reception circuit TRX2 has a function as a transmitting circuit and a function as a receiving circuit. Hence, a signal transmitted from the transmission and reception circuit TRX1 through the transformer TR3 can be received by the transmission and reception circuit TRX2, and a signal transmitted from the transmission and reception circuit TRX2 through the transformer TR3 can also be received by the transmission and reception circuit TRX1.

As such, as illustrated in FIG. 17 and FIG. 18, the semiconductor chip CPL has the pads PL1, PL2, and PL3 as well as a plurality of pads PL4 which are each electrically connected with the transmission and reception circuit TRX1. On the front surface of the semiconductor chip CPL, the plurality of pads PL1, PL2, and PL4 is arranged along the side SL2 of the semiconductor chip CPL, and the plurality of pads PL3 is arranged along the side SL3 of the semiconductor chip CPL. Each of the plurality of pads PL4 of the semiconductor chip CPL is electrically connected with each of the plurality of pads PC5 of the semiconductor chip CPC via each of the plurality of wires BW. In addition, the semiconductor chip CPH has the pads PH1, PH2, and PH3 as well as a plurality of pads PH4 which are each electrically connected with the transmission and reception circuit TRX2. On the front surface of the semiconductor chip CPH, the plurality of pads PH1, PH2, and PH4 is arranged along the side SH3 of the semiconductor chip CPH, and the plurality of pads PH3 is arranged along the side SH1 of the semiconductor chip CPH. Each of the plurality of pads PH4 of the semiconductor chip CPH is electrically connected with each of the plurality of pads PC6 of the semiconductor chip CPC via each of the plurality of wires BW.

In the semiconductor device PKG2 according to the third embodiment, a manner in which the three semiconductor chips CPL, CPC, and CPH are arranged is the same as that of the semiconductor device PKG according to the first embodiment. Hence, also in the third embodiment, effects that are substantially the same as those in the first embodiment can be obtained. In other words, in addition to the effects described in the first embodiment, the plurality of pads PC6 arranged along the side SC1 on the front surface of the semiconductor chip CPC can easily and appropriately be connected with the plurality of pads PH4 of the semiconductor chip CPH via the plurality of wires BW. In addition, the plurality of pads PC5 arranged along the side SC3 on the front surface of the semiconductor chip CPC can easily and appropriately be connected with the plurality of pads PL4 of the semiconductor chip CPL via the plurality of wires BW. Hence, it is possible to appropriately prevent short circuiting between adjacent wires BW, so that the manufacturing yield of the semiconductor device PKG2 can be enhanced.

As a modification example of the third embodiment, the number of transformers formed in the semiconductor chip CPC can also be set to four or more.

### Fourth Embodiment

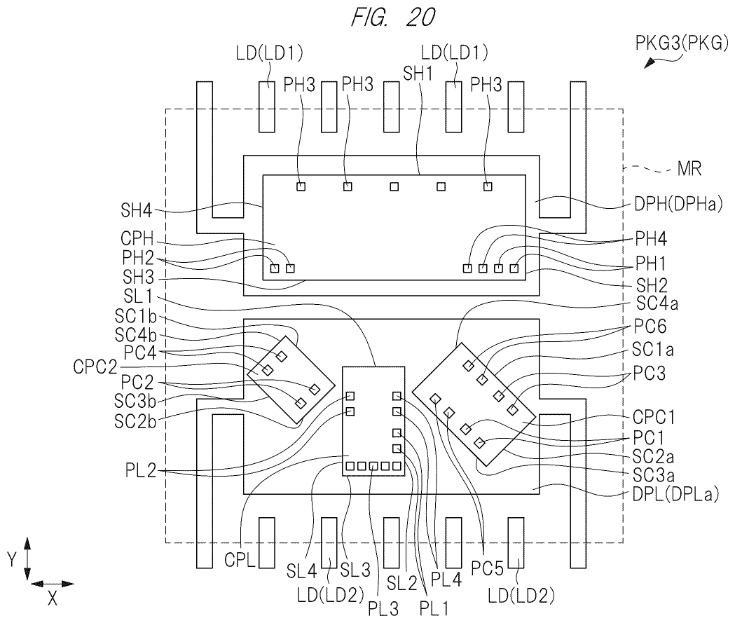

FIG. 19 and FIG. 20 are plan perspective views illustrating the semiconductor device PKG according to the fourth embodiment (hereinafter, referred to as a semiconductor device PKG3). FIG. 19 corresponds to the above-described FIG. 3, and FIG. 20 corresponds to the above-described FIG. 4.

In the following description, with reference to FIG. 19 and FIG. 20, regarding a structure of the semiconductor device PKG3 according to the fourth embodiment, differences from the semiconductor device PKG1 according to the second embodiment will mainly be described. As for points that the semiconductor device PKG3 according to the fourth embodiment has in common with the semiconductor device PKG1 according to the second embodiment, redundant descriptions thereof are omitted as appropriate.

A circuit diagram of an inverter circuit using the semiconductor device PKG3 according to the fourth embodiment is substantially the same as the circuit diagram of FIG. 16, except that two semiconductor chips CPC1 and CPC2 are used in place of the semiconductor chip CPC. Accordingly, according to the fourth embodiment, among the transformers TR1, TR2, and TR3 illustrated in the circuit diagram of FIG. 16, the transformer TR1 (coils L1a and L1b) and the transformer TR3 (coil L3a and L3b) are formed in the semiconductor chip CPC1, and the transformer TR2 (coil L2a and L2b) is formed in the semiconductor chip CPC2. In addition, according to the fourth embodiment, as illustrated in FIG. 16, the semiconductor chip CPL has not only the transmitting circuit TX1 and the receiving circuit RX2 but also the transmission and reception circuit TRX1 formed therein, and the semiconductor chip CPH has not only the receiving circuit RX1, the transmitting circuit TX2, and the drive circuit DR but also the transmission and reception circuit TRX2 formed therein.

Such a configuration is incorporated into the fourth embodiment, so that the pads PC1, PC3, PC5, and PC6 are formed in the semiconductor chip CPC1, the pads PC2 and PC4 are formed in the semiconductor chip CPC2, the pads PL1, PL2, PL3, and PL4 are formed in the semiconductor chip CPL, and the pads PH1, PH2, PH3, and PH4 are formed in the semiconductor chip CPH.

On the front surface of the semiconductor chip CPC1, the plurality of pads PC1 and PC5 is arranged along the side SC3a of the semiconductor chip CPC1, and the plurality of pads PC3 and PC6 is arranged along the side SC1a of the semiconductor chip CPC1. On the front surface of the semiconductor chip CPC2, the plurality of pads PC2 is arranged along the side SC2b of the semiconductor chip CPC2, and the plurality of pads PC4 is arranged along the side SC4b of the semiconductor chip CPC2. On the front surface of the semiconductor chip CPL, the plurality of pads PL1 and PL4 is arranged along the side SL2 of the semiconductor chip CPL, the plurality of pads PL2 is arranged along the side SL4 of the semiconductor chip CPL, and the plurality of pads PL3 is arranged along the side SL3 of the semiconductor chip CPL. Each of the plurality of pads PL4 of the semiconductor chip CPL is electrically connected with each of the plurality of pads PC5 of the semiconductor chip CPC1 via each of the plurality of wires BW. On the front surface of the semiconductor chip CPH, the plurality of pads PH1 and PH4 are disposed close to the side SH2 along the side SH3 of the semiconductor chip CPH, the plurality of pads PH2 are disposed close to the side SH4 along the side SH3 of the semiconductor chip CPH, and the plurality of pads PH3 is arranged along the side SH1 of the semiconductor chip CPH. Each of the plurality of pads PH4 of the semiconductor chip CPH is electrically connected with the plurality of pads PC6 of the semiconductor chip CPC1 via each of the plurality of wires BW.

In the semiconductor device PKG3 according to the fourth embodiment, a manner in which the four semiconductor chips CPL, CPC1, CPC2, and CPH are disposed is the same as that of the semiconductor device PKG1 according to the second embodiment. Hence, also in the fourth embodiment, effects that are substantially the same as those of the above-described second embodiment can be obtained. In other words, in addition to the effects described in the second embodiment, the plurality of pads PC6 arranged along the side SC1a on the front surface of the semiconductor chip CPC1 can easily and appropriately be connected with the plurality of pads PH4 of the semiconductor chip CPH via the plurality of wires BW. In addition, the plurality of pads PC5 arranged along the side SC3a on the front surface of the semiconductor chip CPC1 can easily and appropriately be connected with the plurality of pads PL4 of the semiconductor chip CPL via the plurality of wires BW. Hence, it is possible to appropriately prevent short circuiting between adjacent wires BW, so that the manufacturing yield of the semiconductor device PKG3 can be enhanced.

As a modification example of the fourth embodiment, the number of transformers formed in the semiconductor chip CPC2 can also be set to two or more. In addition, the number of transformers formed in the semiconductor chip CPC1 can also be set to three or more.

### Fifth Embodiment

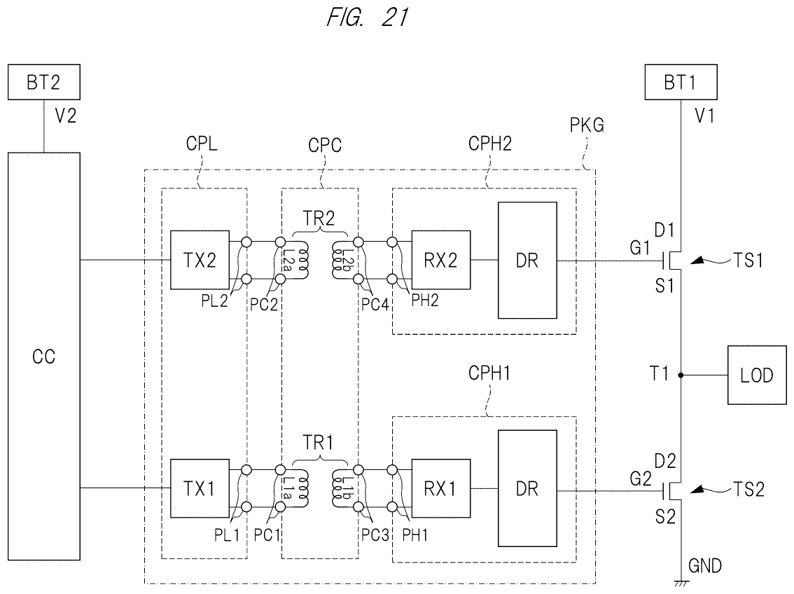

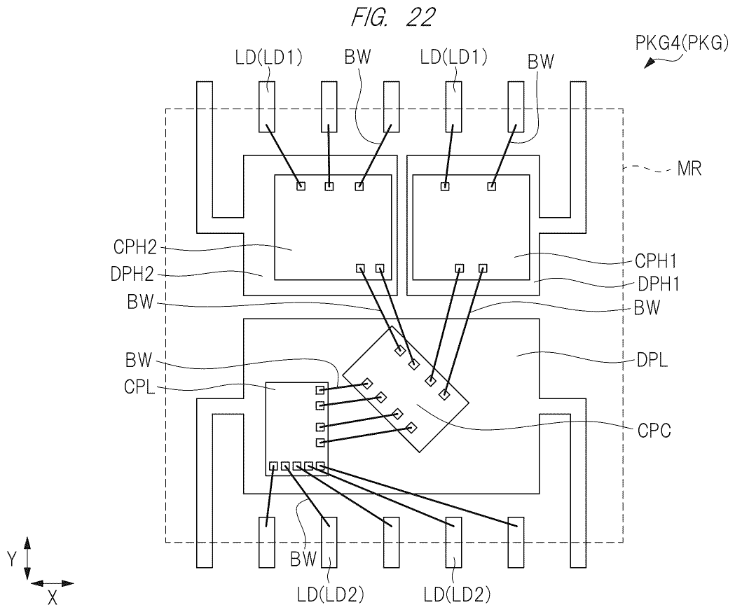

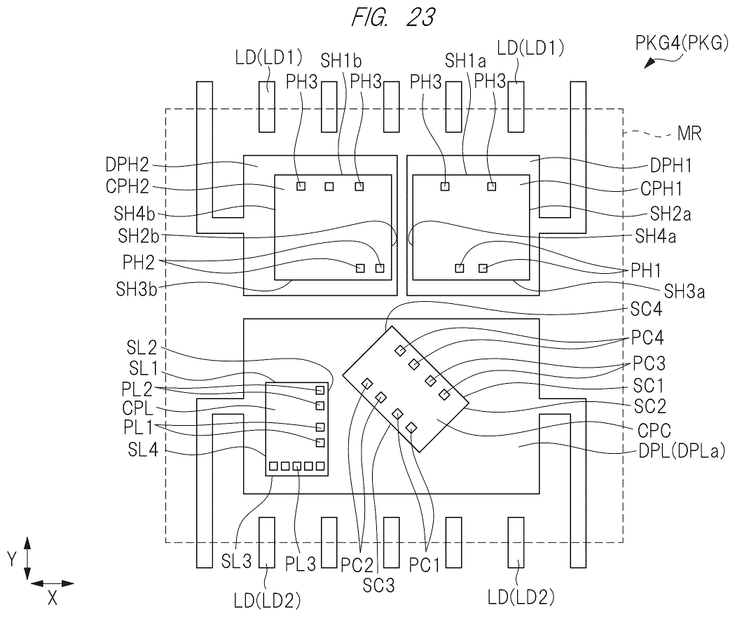

FIG. 21 is a circuit diagram illustrating a DC-DC converter circuit using a semiconductor device PKG according to a fifth embodiment (hereinafter, referred to as a semiconductor device PKG4) and corresponds to the above-described FIG. 1. FIG. 22 and FIG. 23 are plan perspective views of the semiconductor device PKG4 according to the fifth embodiment. FIG. 22 corresponds to the above-described FIG. 3, and FIG. 23 corresponds to the above-described FIG. 4.

In the following description, with reference to FIG. 21 through FIG. 23, regarding a structure of the semiconductor device PKG4 according to the third embodiment, differences from the semiconductor device PKG according to the first embodiment will mainly be described. As for points that the semiconductor device PKG4 according to the fifth embodiment has in common with the semiconductor device PKG according to the first embodiment, redundant descriptions thereof are omitted as appropriate.

As illustrated in FIG. 22 and FIG. 23, the semiconductor device PKG4 according to the fifth embodiment has two semiconductor chips CPH1 and CPH2 in place of the semiconductor chip CPH and has two die pads DPH1 and DPH2 in place of the above-described die pad DPH. The die pad DPH1, the die pad DPH2, and the die pad DPL are spaced apart from one another. The semiconductor chip CPH1 is mounted on the die pad DPH1 with the bonding material interposed therebetween, and the semiconductor chip CPH2 is mounted on the die pad DPH2 with the bonding material interposed therebetween. The semiconductor chips CPH1 and CPH2 and the die pads DPH1 and DPH2 are sealed with the sealing portion MR. The sealing portion MR is partly interposed between the die pad DPH1 and the die pad DPH2, between the die pad DPH1 and the die pad DPL, and between the die pad DPH2 and the die pad DPL.

In the fifth embodiment, as illustrated in FIG. 21, the semiconductor chip CPH1 has the receiving circuit RX1 and the drive circuit DR formed therein. The semiconductor chip CPH2 has the receiving circuit RX2 and the drive circuit DR formed therein. The semiconductor chip CPH1 has a plurality of pads PH1 and PH3, and the semiconductor chip CPH2 has a plurality of pads PH2 and PH3. The plurality of pads PH1 of the semiconductor chip CPH1 are electrically connected with the receiving circuit RX1 of the semiconductor chip CPH1. The plurality of pads PH2 of the semiconductor chip CPH2 are electrically connected with the receiving circuit RX2 of the semiconductor chip CPH2. The semiconductor chip CPL has the transmitting circuit TX1 and the transmitting circuit TX2 formed therein. The semiconductor chip CPL has a plurality of pads PL1, PL2, and PL3. The plurality of pads PL1 are electrically connected with the transmitting circuit TX1, and the plurality of pads PL2 are electrically connected with the transmitting circuit TX2. The configuration of the semiconductor chip CPC according to the fifth embodiment is the same as that of the above-described first embodiment.

According to the fifth embodiment, as illustrated in FIG. 21, one semiconductor device PKG4 is used for the two power transistors TS1 and TS2. The semiconductor chip CPH1 of the semiconductor device PKG4 is connected with the power transistor TS2 for the low-side switch, and the semiconductor chip CPH2 of the semiconductor device PKG4 is connected with the power transistor TS1 for the high-side switch. According to a signal supplied from the control circuit CC to the drive circuit DR in the semiconductor chip CPH1 through the transmitting circuit TX1 in the semiconductor chip CPL, the transformer TR1 in the semiconductor chip CPC, and the receiving circuit RX1 in the semiconductor chip CPH1, a gate voltage supplied from the drive circuit DR in the semiconductor chip CPH1 to the gate G2 of the power transistor TS2 is controlled. In addition, according to a signal supplied from the control circuit CC to the drive circuit DR in the semiconductor chip CPH2 through the transmitting circuit TX2 in the semiconductor chip CPL, the transformer TR2 in the semiconductor chip CPC, and the receiving circuit RX2 in the semiconductor chip CPH2, a gate voltage supplied from the drive circuit DR in the semiconductor chip CPH2 to the gate G1 of the power transistor TS1 is controlled.

Each of the semiconductor chips CPH1 and CPH2 has a front surface that is one main surface, and a back surface that is the other surface opposite to the front surface. A planar shape of each of the semiconductor chips CPH1 and CPH2 is quadrangular, and is preferably rectangular. Hence, in plan view, the semiconductor chip CPH1 has four sides SH1a, SH2a, SH3a, and SH4a, and the semiconductor chip CPH2 has four sides SH1b, SH2b, SH3b, and SH4b.

Among the four sides SH1a, SH2a, SH3a, and SH4a of the semiconductor chip CPH1, the side SH1a and the side SH3a are positioned opposite to each other, and the side SH2a and the side SH4a are positioned opposite to each other. The side SH1a is orthogonal to the sides SH2a and SH4a, and the side SH3a is orthogonal to the sides SH2a and SH4a. In addition, among the four sides SH1b, SH2b, SH3b, and SH4b of the semiconductor chip CPH2, the side SH1b and the side SH3b are positioned opposite to each other, and the side SH2b and the side SH4b are positioned opposite to each other. The side SH1b is orthogonal to the sides SH2b and SH4b, and the side SH3b is orthogonal to the sides SH2b and SH4b. The sides SH1a and SH3a of the semiconductor chip CPH1 and the sides SH1b and SH3b of the semiconductor chip CPH2 are each parallel to the X direction. The sides SH2a and SH4a of the semiconductor chip CPH1 and the sides SH2b and SH4b of the semiconductor chip CPH2 are each parallel to the Y direction.

The die pad DPH1 and the die pad DPH2 are adjacent to each other in the X direction. The die pad DPH1 and the die pad DPL are adjacent to each other in the Y direction. The die pad DPH2 and the die pad DPL are adjacent to each other in the Y direction. The semiconductor chip CPH1 and the semiconductor chip CPH2 are adjacent to each other in the X direction. The side SH4a of the semiconductor chip CPH1 and the side SH2b of the semiconductor chip CPH2 face each other. The semiconductor chip CPL and the semiconductor chip CPC are adjacent to each other in the X direction. The semiconductor chip CPH1 and the semiconductor chip CPC are adjacent to each other in the Y direction. The semiconductor chip CPL and the semiconductor chip CPH2 are adjacent to each other in the Y direction. The side SL1 of the semiconductor chip CPL and the side SH3b of the semiconductor chip CPH2 face each other.

In addition, in the fifth embodiment, in plan view, the side SC3 of the semiconductor chip CPC faces the side SL2 of the semiconductor chip CPL, and the side SC1 of the semiconductor chip CPC faces the side SH3a of the semiconductor chip CPH1. This results from such a layout in which the semiconductor chip CPC is inclined in plan view. In other words, each of the sides SC1, SC2, SC3, and SC4 of the semiconductor chip CPC is inclined to the X direction and to the Y direction. Hence, the side SC3 of the semiconductor chip CPC is inclined to the side SL2 of the semiconductor chip CPL, and the side SC1 of the semiconductor chip CPC is inclined to the side SH3a of the semiconductor chip CPH1. An inclination angle of each of the sides SC1, SC2, SC3, and SC4 of the semiconductor chip CPC to the X direction is preferably in a range of 40 degrees to 50 degrees, and is most preferably 45 degrees.

On the front surface of the semiconductor chip CPH1, the plurality of pads PH1 is arranged along the side SH3a of the semiconductor chip CPH1, and the plurality of pads PH3 is arranged along the side SH1a of the semiconductor chip CPH1. In addition, on the front surface of the semiconductor chip CPH2, the plurality of pads PH2 is arranged along the side SH3b of the semiconductor chip CPH2, and the plurality of pads PH3 is arranged along the side SH1b of the semiconductor chip CPH2. The directions of the sides SL1, SL2, SL3, and SL4 of the semiconductor chip CPL, the directions of the sides SC1, SC2, SC3, and SC4 of the semiconductor chip CPC, the layout of the pads PL1, PL2, and PL3 of the semiconductor chip CPL, and the layout of the pads PC1, PC2, PC3, and PC4 of the semiconductor chip CPC in the fifth embodiment are the same as those of the first embodiment. In addition, in plan view, among four corner portions of the semiconductor chip CPC, a distance (distance in the Y direction) between the corner portion formed by the sides SC4 and SC1 and the semiconductor chip CPH1 is smaller than a distance (distance in the Y direction) between each of the other corner portions of the semiconductor chip CPC and the semiconductor chip CPH1.

Next, effects of the semiconductor device PKG4 according to the fifth embodiment will be described.

In the semiconductor device PKG4 of the fifth embodiment, the semiconductor chip CPH1 is mounted on the die pad DPH1, the semiconductor chip CPH2 is mounted on the die pad DPH2 positioned to be adjacent to the die pad DPH1 in the X direction, the semiconductor chip CPL and the semiconductor chip CPC are mounted on the die pad DPL positioned to be adjacent to the die pads DPH1 and DPH2 in the Y direction. Then, the semiconductor chip CPH1 and the semiconductor chip CPH2 are adjacent to each other in the X direction, the semiconductor chip CPC and the semiconductor chip CPL are adjacent to each other in the X direction, and the semiconductor chip CPC and the semiconductor chip CPH1 are adjacent to each other in the Y direction. Owing to this layout, even if the aspect ratio of each of the semiconductor chips CPH1, CPH2, CPC, and CPL is not increased, the size of the semiconductor device PKG4 in the Y direction according to the present embodiment can be made smaller. As a result, the size reduction of the semiconductor device PKG4 can be achieved. In addition, since the aspect ratio of each of the semiconductor chips CPH1, CPH2, CPC, and CPL can be reduced, a risk of occurrence of cracks in the semiconductor chips CPH1, CPH2, CPC, and CPL can be reduced at, for example, a time of obtaining a semiconductor chip as a result of cutting a semiconductor wafer, a time of transferring a semiconductor chip, or the like. Hence, the manufacturing yield of the semiconductor chips CPH1, CPH2, CPC, and CPL and the manufacturing yield of the semiconductor device PKG4 can be enhanced.

In addition, in the semiconductor device PKG4 according to the fifth embodiment, in plan view, the side SC3 of the semiconductor chip CPC and the side SL2 of the semiconductor chip CPL face each other. Hence, the plurality of pads PC1 and PC2 arranged along the side SC3 on the front surface of the semiconductor chip CPC can easily and appropriately be connected with the plurality of pads PL1 and PL2 of the semiconductor chip CPL via the plurality of wires BW, respectively. In addition, in plan view, the side SC1 of the semiconductor chip CPC and the side SH3a of the semiconductor chip CPH1 face each other. Hence, the plurality of pads PC3 arranged along the side SC1 on the front surface of the semiconductor chip CPC can easily and appropriately be connected with the plurality of pads PH1 of the semiconductor chip CPH1 via the plurality of wires BW. In addition, the plurality of pads PC4 arranged along the side SC1 on the front surface of the semiconductor chip CPC can easily and appropriately be connected with the plurality of pads PH2 of the semiconductor chip CPH2 via the plurality of wires BW. Hence, it is possible to appropriately prevent short circuiting between adjacent wires BW, so that the manufacturing yield of the semiconductor device PKG4 can be enhanced.

In addition, in the fifth embodiment, the number of transformers formed in the semiconductor chip CPC is two. As a modification example of the fifth embodiment, the number of transformers formed in the semiconductor chip CPC can also be set to be three or more.

### Sixth Embodiment

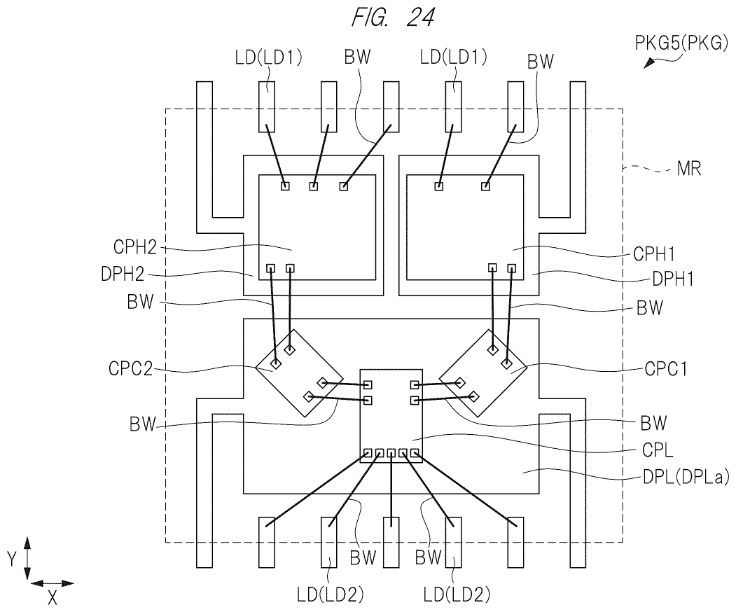

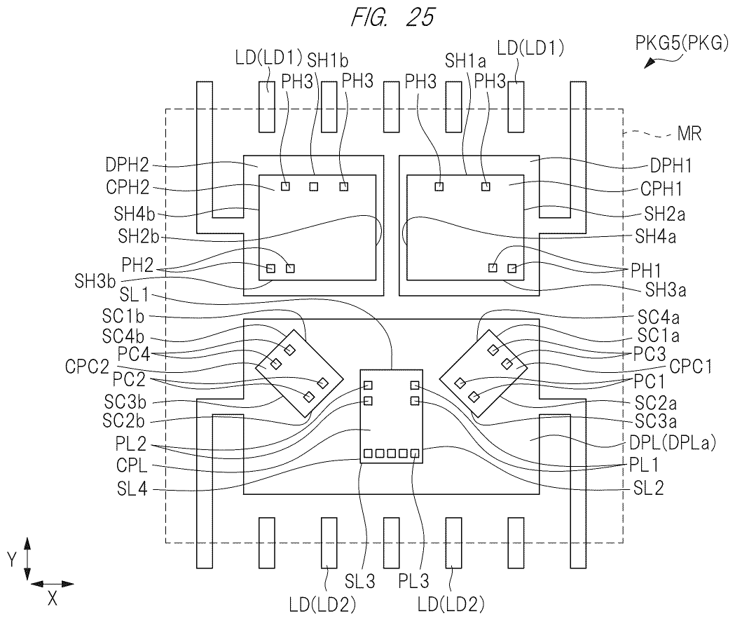

FIG. 24 and FIG. 25 are each a plan perspective view of a semiconductor device PKG (hereinafter, referred to as a semiconductor device PKG5) according to a sixth embodiment. FIG. 24 corresponds to the above-described FIG. 3, and FIG. 25 corresponds to the above-described FIG. 4.

In the following description, with reference to FIG. 24 and FIG. 25, a structure of the semiconductor device PKG5 according to the sixth embodiment, differences from the semiconductor device PKG4 according to the fifth embodiment will mainly be described. As for points that the semiconductor device PKG5 according to the sixth embodiment has in common with the semiconductor device PKG4 according to the fifth embodiment, redundant descriptions thereof are omitted as appropriate.

A circuit diagram of a DC-DC converter circuit using the semiconductor device PKG5 according to the sixth embodiment is substantially the same as that of the circuit diagram in FIG. 21, except that two semiconductor chips CPC1 and CPC2 are used in place of the semiconductor chip CPC. Accordingly, in the sixth embodiment, among the transformers TR1 and TR2 illustrated in the circuit diagram of FIG. 21, the transformer TR1 (coils L1a and L1b) is formed in the semiconductor chip CPC1, and the transformer TR2 (coils L2a and L2b) is formed in the semiconductor chip CPC2.

As illustrated in FIG. 24 and FIG. 25, the semiconductor device PKG5 according to the sixth embodiment has two semiconductor chips CPC1 and CPC2 in place of the semiconductor chip CPC. The semiconductor chips CPC1 and CPC2 are sealed with the sealing portion MR. Among the transformers TR1 and TR2 illustrated in the circuit diagram in FIG. 21, the transformer TR1 (coils L1a and L1b) is formed in the semiconductor chip CPC1, and the transformer TR2 (coils L2a and L2b) is formed in the semiconductor chip CPC2. Accordingly, among the pads PC1, PC2, PC3, and PC4, the pads PC1 and PC3 are formed in the semiconductor chip CPC1, and the pads PC2 and PC4 are formed in the semiconductor chip CPC2. A configuration of the semiconductor chip CPC1 and a configuration of the semiconductor chip CPC2 of the sixth embodiment are also the same as those of the second embodiment. In addition, layout of the semiconductor chip CPC1, the semiconductor chip CPC2, and the semiconductor chip CPL of the sixth embodiment is also the same as that of the second embodiment.

In the semiconductor device PKG5 according to the sixth embodiment, three semiconductor chips CPL, CPC1, and CP2 are mounted on the die pad DPL via a bonding material, one semiconductor chip CPH1 is mounted on the die pad DPH1 via a bonding material, and one semiconductor chip CPH2 is mounted on the die pad DPH2 via a bonding material.

A direction of each of the sides SL1, SL2, SL3, and SL4 of the semiconductor chip CPL, a direction of each of the sides SH1a, SH2a, SH3a, and SH4a of the semiconductor chip CPH1, a direction of each of the sides SH1b, SH2b, SH3b, and SH4b of the semiconductor chip CPH2 of the sixth embodiment are also the same as those of the fifth embodiment. In addition, a direction of each of the sides SC1a, SC2a, SC3a, and SC4a of the semiconductor chip CPC1, a direction of each of the sides SC1b, SC2b, SC3b, and SC4b of the semiconductor chip CPC2, layout of the pads PC1 and PC3 of the semiconductor chip CPC1, layout of the pad PC2 and PC4 of the semiconductor chip CPC2, and layout of the pads PL1, PL2, and PL3 of the semiconductor chip CPL of the sixth embodiment are also the same as those of the second embodiment. In addition, on the front surface of the semiconductor chip CPH1, the plurality of pads PH1 are disposed close to the side SH2a along the side SH3a of the semiconductor chip CPH1, and the plurality of pads PH3 is arranged along the side SH1a of the semiconductor chip CPH1. In addition, on the front surface of the semiconductor chip CPH2, the plurality of pads PH2 are disposed close to the side SH4b along the side SH3b of the semiconductor chip CPH2, and the plurality of pads PH3 is arranged along the side SHib of the semiconductor chip CPH2.

In plan view, among four corner portions of the semiconductor chip CPC1, a distance (distance in the Y direction) between the corner portion formed by the sides SC4a and SC1a and the semiconductor chip CPH1 is smaller than a distance (distance in the Y direction) between each of the other corner portions of the semiconductor chip CPC1 and the semiconductor chip CPH1. In addition, in plan view, among four corner portions of the semiconductor chip CPC2, a distance (distance in the Y direction) between the corner portion formed by the sides SC4b and SCib and the semiconductor chip CPH2 is smaller than a distance (distance in the Y direction) between each of the other corner portions of the semiconductor chip CPC2 and the semiconductor chip CPH2.

In the semiconductor device PKG5 according to the sixth embodiment, in plan view, the side SC1a of the semiconductor chip CPC1 and the side SH3a of the semiconductor chip CPH1 face each other. Hence, the plurality of pads PC3 arranged along the side SC1a on the front surface of the semiconductor chip CPC1 can easily and appropriately be connected with the plurality of pads PH1 of the semiconductor chip CPH1 via the plurality of wires BW. In addition, in plan view, the side SC3a of the semiconductor chip CPC1 and the side SL2 of the semiconductor chip CPL face each other. Hence, the plurality of pads PC1 arranged along the side SC3a on the front surface of the semiconductor chip CPC1 can easily and appropriately be connected with the plurality of pads PL1 of the semiconductor chip CPL via the plurality of wires BW. In addition, in plan view, the side SC4b of the semiconductor chip CPC2 and the side SH3b of the semiconductor chip CPH2 face each other. Hence, the plurality of pads PC4 arranged along the side SC4b on the front surface of the semiconductor chip CPC2 can easily and appropriately be connected with the plurality of pads PH2 of the semiconductor chip CPH2 via the plurality of wires BW. In addition, in plan view, the side SC2b of the semiconductor chip CPC2 and the side SL4 of the semiconductor chip CPL face each other. Hence, the plurality of pads PC2 arranged along the side SC2b on the front surface of the semiconductor chip CPC2 can easily and appropriately be connected with the plurality of pads PL2 of the semiconductor chip CPL via the plurality of wires BW. Hence, it is possible to appropriately prevent short circuiting between adjacent wires BW, so that the manufacturing yield of the semiconductor device PKG can be enhanced.

In the sixth embodiment, effects that are substantially the same as those of the fifth embodiment can be obtained, and further, owing to formation of the transformer TR1 (coils L1a and L1b) in the semiconductor chip CPC1 and formation of the transformer TR2 (coils L2a and L2b) in the semiconductor chip CPC2, the coupling noise between the transformer TR1 and transformer TR2 can be reduced. Hence, performance of the semiconductor device PKG5 can further be enhanced.

In contrast, in the case of the fifth embodiment, the transformer TR1 (coils L1a and L1b) and the transformer TR2 (coils L2a and L2b) are formed in the semiconductor chip CPC, so that the number of semiconductor chips included in the semiconductor device PKG4 can be reduced. Hence, the manufacturing costs of the semiconductor device PKG4 can be reduced.

As a modification example of the sixth embodiment, the number of transformers formed in the semiconductor chip CPC1 can also be set to be two or more. In addition, the number of transformers formed in the semiconductor chip CPC2 can also be set to be two or more.

In the foregoing, the invention made by the inventors of the present invention has been concretely described on the basis of the embodiments. However, it is needless to say that the present invention is not limited to the foregoing embodiments and various modifications and alterations can be made within the scope of the present invention.

In the above-described first to sixth embodiments, each of the semiconductor chips CPC, CPC1, and CPC2 has one or more transformers formed therein. However, a capacitive element (capacitor) can also be used in place of the transformer. The capacitive element includes two electrodes (specifically, an upper electrode and a lower electrode facing each other) capacitively coupled with each other. Also, in a case in which the capacitive element is used in place of the transformer, it is possible to transmit a signal from the transmitting circuit to the receiving circuit through the capacitive element. In the case in which the capacitive element is used in place of the transformer, in the above-described first to sixth embodiments, the transformer TR1 may be rephrased as the capacitive element TR1, the transformer TR2 as the capacitive element TR2, the transformer TR3 as the capacitive element TR3, the coil L1a, the coil L1b, the coil L2a, the coil L2b, the coil L3a, and the coil L3b as the electrode L1a, the electrode L1b, the electrode L2a, the electrode L2b, the electrode L3a, and the electrode L3b, respectively. In this case, the electrode L1a and the electrode L1b are capacitively coupled with each other, the electrode L2a and the electrode L2b are capacitively coupled with each other, and the electrode L3a and the electrode L3b are capacitively coupled with each other. The coil L1a, the coil L1b, the coil L2a, the coil L2b, the coil L3a, and the coil L3b are formed of spiral conductive patterns, and the electrode L1a, the electrode L1b, the electrode L2a, the electrode L2b, the electrode L3a, and the electrode L3b are formed of plate-shaped conductive patterns. The transformer is formed of two (a pair of) conductive patterns magnetically coupled with each other, and the capacitive element is formed of two (a pair of) conductive patterns capacitively coupled with each other.

What is claimed is:

1. A semiconductor device comprising:
a first chip mounting portion;
a second chip mounting portion spaced apart from the first chip mounting portion;
a first semiconductor chip mounted on the first chip mounting portion and including: a first side, a first circuit, and a plurality of first chip pads arranged along the first side and electrically connected with the first circuit;
a second semiconductor chip mounted on the second chip mounting portion and including: a second side, a second circuit, and a plurality of second chip pads arranged along the second side and electrically connected with the second circuit;
a third semiconductor chip mounted on the first chip mounting portion and including: a third side, a fourth side opposite the third side, two first conductor patterns magnetically or capacitively coupled with each other, a plurality of first pattern pads arranged along the third side and electrically connected with a one of the two first conductor patterns, and a plurality of second pattern pads arranged along the fourth side and electrically connected with an other of the two first conductor patterns;
a plurality of first wires electrically connecting the plurality of first chip pads with the plurality of first pattern pads, respectively;
a plurality of second wires electrically connecting the plurality of second chip pads with the plurality of second pattern pads, respectively; and
a resin sealing body sealing the first semiconductor chip, the second semiconductor chip, the third semiconductor chip, the first chip mounting portion, the second chip mounting portion, the plurality of first wires, and the plurality of second wires,
wherein the first chip mounting portion and the second chip mounting portion are adjacent to each other in a first direction,
wherein a planar shape of the first semiconductor chip is formed of a quadrangle including the first side,
wherein a planar shape of the second semiconductor chip is formed of a quadrangle including the second side,
wherein a planar shape of the third semiconductor chip is formed of a quadrangle including the third side and the fourth side,
wherein a length of the second side is greater than a length of each of the first side, the third side, and the fourth side,
wherein the first semiconductor chip and the third semiconductor chip are adjacent to each other in a second direction orthogonal to the first direction, and
wherein, in plan view, the first semiconductor chip and the third semiconductor chip are arranged along the second side of the second semiconductor chip such that the third side of the third semiconductor chip faces the first side of the first semiconductor chip and such that the fourth side of the third semiconductor chip faces the second side of the second semiconductor chip.

2. The semiconductor device according to claim 1,
wherein, in plan view, the third side of the third semiconductor chip is inclined to the first side of the first semiconductor chip, and the fourth side of the third semiconductor chip is inclined to the second side of the second semiconductor chip.

3. The semiconductor device according to claim 1,
wherein each of the first circuit and the second circuit is a transmitting circuit or a receiving circuit, and
wherein the two first conductor patterns form a transformer or a capacitive element.

4. The semiconductor device according to claim 3,
wherein the second semiconductor chip further includes a drive circuit.

5. The semiconductor device according to claim 1,
wherein the first semiconductor chip further includes: a third circuit; and a plurality of third chip pads arranged along the first side and electrically connected with the third circuit,
wherein the second semiconductor chip further includes: a fourth circuit; and a plurality of fourth chip pads arranged along the second side and electrically connected with the fourth circuit,
wherein the third semiconductor chip further includes: two second conductor patterns magnetically or capacitively coupled with each other; a plurality of third pattern pads arranged along the third side and electrically connected with a one of the two second conductor patterns; and a plurality of fourth pattern pads arranged along the fourth side and electrically connected with an other of the two second conductor patterns,
wherein each of the plurality of third chip pads is electrically connected with each of the plurality of third pattern pads via each of a plurality of third wires,
wherein each of the plurality of fourth chip pads is electrically connected with each of the plurality of fourth pattern pads via each of a plurality of fourth wires, and
wherein the first semiconductor chip, the second semiconductor chip, the third semiconductor chip, the first chip mounting portion, the second chip mounting portion, the plurality of first wires, the plurality of second wires, the plurality of third wires, and the plurality of fourth wires are sealed with the resin sealing body.

6. The semiconductor device according to claim 5,
wherein the first semiconductor chip further includes: a fifth circuit; and a plurality of fifth chip pads arranged along the first side and electrically connected with the fifth circuit,
wherein the second semiconductor chip further includes: a sixth circuit; and a plurality of sixth chip pads arranged along the second side and electrically connected with the sixth circuit,
wherein the third semiconductor chip further includes: two third conductor patterns magnetically or capacitively coupled with each other; a plurality of fifth pattern pads arranged along the third side and electrically connected with a one of the two third conductor patterns; and a plurality of sixth pattern pads arranged along the fourth side and electrically connected with an other of the two third conductor patterns,
wherein each of the plurality of fifth chip pads is electrically connected with each of the plurality of fifth pattern pads via each of a plurality of fifth wires,
wherein each of the plurality of sixth chip pads is electrically connected with each of the plurality of sixth pattern pads via each of a plurality of sixth wires, and
wherein the first semiconductor chip, the second semiconductor chip, the third semiconductor chip, the first chip mounting portion, the second chip mounting portion, the plurality of first wires, the plurality of second wires, the plurality of third wires, the plurality of fourth wires, the plurality of fifth wires, and the plurality of sixth wires are sealed with the resin sealing body.

7. The semiconductor device according to claim 1, further comprising:
a fourth semiconductor chip mounted on the first chip mounting portion and including: a fifth side; a sixth side opposite to the fifth side; two second conductor patterns magnetically or capacitively coupled with each other; a plurality of third pattern pads arranged along the fifth side and electrically connected with a one of the two second conductor patterns; and a plurality of fourth pattern pads arranged along the sixth side and electrically connected with an other of the two second conductor patterns,
wherein the first semiconductor chip further includes: a seventh side opposite to the first side; a third circuit; and a plurality of third chip pads arranged along the seventh side and electrically connected with the third circuit,
wherein the second semiconductor chip further includes: a fourth circuit; and a plurality of fourth chip pads arranged along the second side and electrically connected with the fourth circuit,
wherein a planar shape of the fourth semiconductor chip is formed of a quadrangle including the fifth side and the sixth side,
wherein the first semiconductor chip and the fourth semiconductor chip are adjacent to each other in the second direction,
wherein the first semiconductor chip is positioned between the third semiconductor chip and the fourth semiconductor chip in the second direction,
wherein each of the plurality of third chip pads is electrically connected with each of the plurality of third pattern pads via each of the plurality of third wires,
wherein each of the plurality of fourth chip pads is electrically connected with each of the plurality of fourth pattern pads via each of the plurality of fourth wires,
wherein the first semiconductor chip, the second semiconductor chip, the third semiconductor chip, the fourth semiconductor chip, the first chip mounting portion, the second chip mounting portion, the plurality of first wires, the plurality of second wires, the plurality of third wires, and the plurality of fourth wires are sealed with the resin sealing body, and
wherein, in plan view, the first semiconductor chip, the third semiconductor chip, and the fourth semiconductor chip are arranged along the second side of the second semiconductor chip such that the third side of the third semiconductor chip faces the first side of the first semiconductor chip, the fourth side of the third semiconductor chip faces the second side of the second semiconductor chip, the fifth side of the fourth semiconductor chip faces the seventh side of the first semiconductor chip, and the sixth side of the fourth semiconductor chip faces the second side of the second semiconductor chip.

8. The semiconductor device according to claim 7,
wherein, in plan view, the third side of the third semiconductor chip is inclined to the first side of the first semiconductor chip, the fourth side of the third semiconductor chip is inclined to the second side of the second semiconductor chip, the fifth side of the fourth semiconductor chip is inclined to the seventh side of the first semiconductor chip, and the sixth side of the fourth semiconductor chip is inclined to the second side of the second semiconductor chip.

9. The semiconductor device according to claim 8,
wherein each of the first circuit, the second circuit, the third circuit, and the fourth circuit is a transmitting circuit or a receiving circuit, and
wherein each of the two first conductor patterns and the two second conductor patterns forms a transformer or a capacitive element.

10. The semiconductor device according to claim 7,
wherein the first semiconductor chip further includes: a fifth circuit; and a plurality of fifth chip pads arranged along the first side and electrically connected with the fifth circuit,
wherein the second semiconductor chip further includes: a sixth circuit; and a plurality of sixth chip pads arranged along the second side and electrically connected with the sixth circuit,
wherein the third semiconductor chip further includes: two third conductor patterns magnetically or capacitively coupled with each other; a plurality of fifth pattern pads arranged along the third side and electrically connected with a one of the two third conductor patterns; and a plurality of sixth pattern pads arranged along the fourth side and electrically connected with an other of the two third conductor patterns,
wherein each of the plurality of fifth chip pads is electrically connected with each of the plurality of fifth pattern pads via each of the plurality of fifth wires,
wherein each of the plurality of sixth chip pads is electrically connected with each of the plurality of sixth pattern pads via each of the plurality of sixth wires, and
wherein the first semiconductor chip, the second semiconductor chip, the third semiconductor chip, the fourth semiconductor chip, the first chip mounting portion, the second chip mounting portion, the plurality of first wires, the plurality of second wires, the plurality of third wires, the plurality of fourth wires, the plurality of fifth wires, and the plurality of sixth wires are sealed with the resin sealing body.

11. A semiconductor device comprising:
a first chip mounting portion;
a second chip mounting portion spaced apart from the first chip mounting portion;
a third chip mounting portion spaced apart from each of the first chip mounting portion and the second chip mounting portion;
a first semiconductor chip mounted on the first chip mounting portion and including: a first side, a first circuit, and a plurality of first chip pads arranged along the first side and electrically connected with the first circuit;
a second semiconductor chip mounted on the second chip mounting portion and including: a second side, a second circuit, and a plurality of second chip pads arranged along the second side and electrically connected with the second circuit;
a third semiconductor chip mounted on the third chip mounting portion and including: a third side, a third circuit, and a plurality of third chip pads arranged along the third side and electrically connected with the third circuit;
a fourth semiconductor chip mounted on the first chip mounting portion and including: a fourth side, a fifth side opposite the fourth side, two first conductor patterns magnetically or capacitively coupled with each other, a plurality of first pattern pads arranged along the fourth side and electrically connected with a one of the two first conductor patterns, and a plurality of second pattern pads arranged along the fifth side and electrically connected with an other of the two first conductor patterns;
a plurality of first wires electrically connecting the plurality of first chip pads with the plurality of first pattern pads, respectively;
a plurality of second wires electrically connecting the plurality of second chip pads with the plurality of second pattern pads, respectively; and
a resin sealing body sealing the first semiconductor chip, the second semiconductor chip, the third semiconductor chip, the fourth semiconductor chip, the first chip mounting portion, the second chip mounting portion, the plurality of first wires, and the plurality of second wires,
wherein the first chip mounting portion and the second chip mounting portion are adjacent to each other in a first direction,
wherein the first chip mounting portion and the third chip mounting portion are adjacent to each other in the first direction,
wherein the second chip mounting portion and the third chip mounting portion are adjacent to each other in a second direction orthogonal to the first direction,
wherein a planar shape of the first semiconductor chip is formed of a quadrangle including the first side,
wherein a planar shape of the second semiconductor chip is formed of a quadrangle including the second side,
wherein a planar shape of the third semiconductor chip is formed of a quadrangle including the third side,
wherein a planar shape of the fourth semiconductor chip is formed of a quadrangle including the fourth side and the fifth side,
wherein the first semiconductor chip and the fourth semiconductor chip are adjacent to each other in the second direction, and
wherein, in plan view, the first semiconductor chip and the fourth semiconductor chip are arranged along the second side of the second semiconductor chip such that the fourth side of the fourth semiconductor chip faces the first side of the first semiconductor chip and such that the fifth side of the fourth semiconductor chip faces the second side of the second semiconductor chip.

12. The semiconductor device according to claim 11,
wherein the first semiconductor chip further includes: a fourth circuit; and a plurality of fourth chip pads arranged along the first side and electrically connected with the fourth circuit,
wherein the fourth semiconductor chip further includes: two second conductor patterns magnetically or capacitively coupled with each other; a plurality of third pattern pads arranged along the fourth side and electrically connected with one of the two second conductor patterns; and a plurality of fourth pattern pads arranged along the fifth side and electrically connected with the other of the two second conductor patterns,
wherein each of the plurality of fourth chip pads is electrically connected with each of the plurality of third pattern pads via each of a plurality of third wires,
wherein each of the plurality of third chip pads is electrically connected with each of the plurality of fourth pattern pads via each of a plurality of fourth wires, and
wherein the first semiconductor chip, the second semiconductor chip, the third semiconductor chip, the fourth semiconductor chip, the first chip mounting portion, the second chip mounting portion, the plurality of first wires, the plurality of second wires, the plurality of third wires, and the plurality of fourth wires are sealed with the resin sealing body.

13. The semiconductor device according to claim 11, further comprising:
a fifth semiconductor chip mounted on the first chip mounting portion and including: a sixth side; a seventh side opposite to the sixth side; two second conductor patterns magnetically or capacitively coupled with each other; a plurality of third pattern pads arranged along the sixth side and electrically connected with one of the two second conductor patterns; and a plurality of fourth pattern pads arranged along the seventh side and electrically connected with the other of the two second conductor patterns,
wherein the first semiconductor chip further includes: an eighth side opposite to the first side; a fourth circuit; and a plurality of fourth chip pads arranged along the eighth side and electrically connected with the fourth circuit,
wherein a planar shape of the fifth semiconductor chip is formed of a quadrangle including the sixth side and the seventh side,
wherein the first semiconductor chip and the fifth semiconductor chip are adjacent to each other in the second direction,
wherein the first semiconductor chip is positioned between the fourth semiconductor chip and the fifth semiconductor chip in the second direction,
wherein each of the plurality of fourth chip pads is electrically connected with each of the plurality of third pattern pads via each of a plurality of third wires,
wherein each of the plurality of third chip pads is electrically connected with each of the plurality of fourth pattern pads via each of a plurality of fourth wires,
wherein the first semiconductor chip, the second semiconductor chip, the third semiconductor chip, the fourth semiconductor chip, the fifth semiconductor chip, the first chip mounting portion, the second chip mounting portion, the plurality of first wires, the plurality of second wires, the plurality of third wires, and the plurality of fourth wires are sealed with the resin sealing body, and
wherein, in plan view, the first semiconductor chip, the fourth semiconductor chip, and the fifth semiconductor chip are arranged along each of the second side of the second semiconductor chip and the third side of the third semiconductor chip such that the fourth side of the fourth semiconductor chip faces the first side of the first semiconductor chip, the fifth side of the fourth semiconductor chip faces the second side of the second semiconductor chip, the sixth side of the fifth semiconductor chip faces the eighth side of the first semiconductor chip, and the seventh side of the fifth semiconductor chip faces the third side of the third semiconductor chip.
